(19) United States
(12) Patent Application Publication
(10) Pub. No.: US 2016/0020420 A1
(43) Pub. Date: Jan. 21, 2016

(54) ELECTRONIC ELEMENT EMPLOYING HYBRID ELECTRODE HAVING HIGH WORK FUNCTION AND CONDUCTIVITY

(71) Applicant: POSTECH ACADEMY-INDUSTRY FOUNDATION, Pohang-si, Gyeongsangbuk-do (KR)

(72) Inventors: Tae-Woo LEE, Pohang-si (KR); Su-Hun JEONG, Busan (KR)

(73) Assignee: POSTECH ACADEMY - INDUSTRY FOUNDATION, Pohang-si, Gyeongsangbuk-do (KR)

(21) Appl. No.: 14/771,184

(22) PCT Filed: Feb. 28, 2014
(86) PCT No.: PCT/KR2014/001711

§ 371 Date: Aug. 27, 2015

(30) Foreign Application Priority Data
Feb. 28, 2013 (KR) 10-2013-0022500
Feb. 28, 2013 (KR) 10-2013-0022501

(51) Int. Cl. H01L 51/44; H01L 51/10; H01L 51/52

(52) U.S. Cl. CPC H01L 51/442; H01L 51/5215; H01L 51/102; H01L 2251/308; H01L 2251/305; H01L 2251/301; H01L 2251/5369

(57) ABSTRACT

An electronic element is provided. The electronic element may include a hybrid electrode having a high work function and conductivity which has a conductivity of at least 1 S/cm and includes: a work function-tuning layer; and a conductivity-tuning layer which is in contact with the first surface of the work function-tuning layer. Accordingly, the electronic element which employs the hybrid electrode having a high work function and conductivity may have excellent light-emitting efficiency and/or photoelectric conversion efficiency even if a hole injection layer for work function adjustment is omitted.

### TECHNICAL FIELD

The present invention relates to an electronic element, and more specifically, to an electronic element employing a hybrid electrode having a high work function and high conductivity.

### BACKGROUND ART

Currently, indium tin oxide (ITO) transparent electrodes are being widely used as essential components in various electronic elements such as solar cells and display elements.

Oxide electrodes such as ITO have high electric conductivity and transparency, but are vulnerable to bending. Due to cracks which occur when ITO transparent electrodes are bent, resistance increases, and it is difficult to reuse the transparent electrodes after cracks occur. Also, indium, which is a main material of ITO, is very expensive and is not easy to process. As a demand thereof increases, there is a problem of a cost increase which results from a raw material cost increase.

Accordingly, transparent electrode elements of different types that can replace ITO transparent electrode elements of the related art are under development, but conductivity and a work function do not reach satisfactory levels.

### DISCLOSURE

### Technical Problem

The present invention provides an electronic element employing a hybrid electrode having a high work function and high conductivity.

### Technical Solution

In order to address the above problems, according to an aspect of the present invention, there is provided an electronic element including a hybrid electrode having a high work function and conductivity. The electronic element includes, a work function-tuning layer that includes a material having low surface energy, does not include a conductive material, and has a first surface and a second surface that faces the first surface and has a work function of 5.0 eV or more; and a conductivity-tuning layer that includes at least one of a conductive polymer, a metallic carbon nanotube, a graphene, a reduced graphene oxide, a metallic nanowire, a semiconductor nanowire, a metallic grid, a metallic nanodot and a conductive oxide, does not include the material having low surface energy, and is in contact with the first surface of the work function-tuning layer.

The material having low surface energy may be a fluorinated material including at least one fluorine atom.

The electronic element may be an organic light-emitting element, an organic solar cell, an organic transistor, an organic memory element, an organic photodetector or an organic CMOS sensor.

The electronic element may be an organic light-emitting element, the organic light-emitting element may include a substrate, a first electrode, a second electrode and a light-emitting layer positioned between the first electrode and the second electrode, the first electrode may be a hybrid electrode having a high work function and high conductivity, and a work function-tuning layer may be positioned between the light-emitting layer and the conductivity-tuning layer in the hybrid electrode having a high work function and high conductivity.

The electronic element may be an organic solar cell, the organic solar cell may include a substrate, a first electrode, a second electrode, and a photoactive layer positioned between the first electrode and the second electrode, the first electrode may be a hybrid electrode having a high work function and high conductivity, and a work function-tuning layer may be positioned between the photoactive layer and the conductivity-tuning layer in the hybrid electrode having a high work function and high conductivity.

### Advantageous Effects

Since the hybrid electrode having a high work function and high conductivity includes a work function-tuning layer and a conductivity-tuning layer, excellent work function and conductivity can be obtained. Therefore, the electronic element employing the hybrid electrode having a high work function and high conductivity can have excellent light-emitting efficiency and/or photoelectric conversion efficiency even without a hole injection layer for work function adjustment.

### DESCRIPTION OF DRAWINGS

FIG. 1 is a diagram schematically illustrating a cross section of an implementation example of an organic light-emitting element that is an example of an electronic element.

FIG. 2 schematically illustrating a work function relation among a substrate, a hybrid electrode having a high work function and high conductivity (including a conductivity-tuning layer and a work function-tuning layer) and a hole transport layer of the organic light-emitting element of FIG. 1.

FIG. 3 is a diagram schematically illustrating a cross section of an implementation example of an organic solar cell that is an example of the electronic element.

FIG. 4 is a diagram schematically illustrating a cross section of an implementation example of an organic thin film transistor that is an example of the electronic element.

### MODES OF THE INVENTION

Hereinafter, exemplary examples of the present invention will be described in detail with reference to the accompanying drawings.

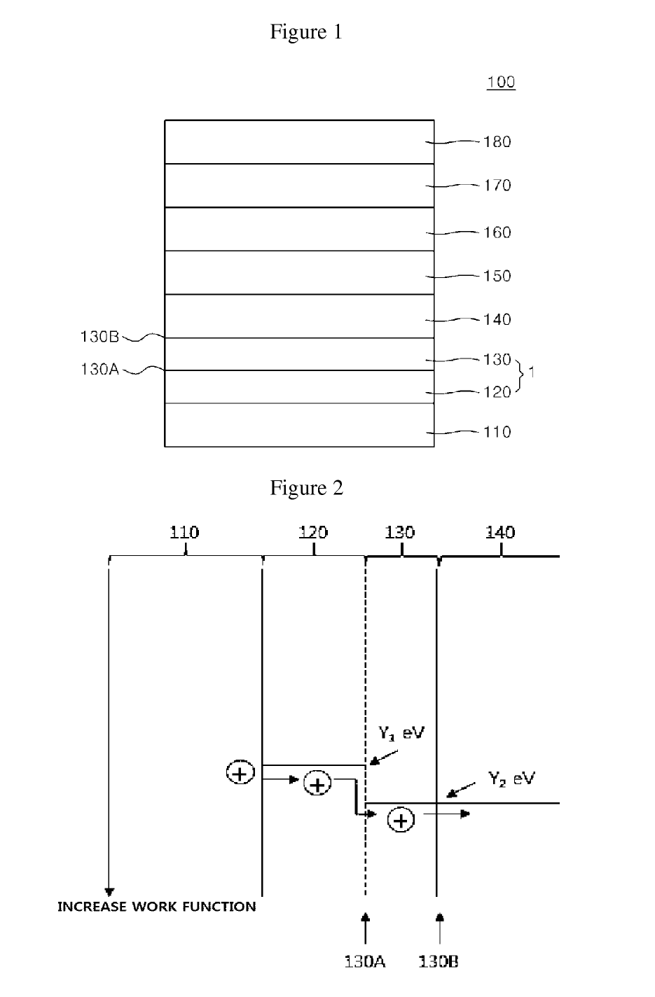

An organic light-emitting element 100 of FIG. 1 includes a substrate 110, a hybrid electrode having a high work function and high conductivity 1, a hole transport layer 140, a light-emitting layer 150, an electron transport layer 160, an electron injection layer 170 and an second electrode 180.

The hybrid electrode having a high work function and high conductivity 1 includes a conductivity-tuning layer 120 and a work function-tuning layer 130, and serves as an anode. The conductivity-tuning layer 120 of the hybrid electrode having a high work function and high conductivity 1 is positioned between the substrate 110 and the work function-tuning layer 130.

When a voltage is applied between the hybrid electrode having a high work function and high conductivity 1 serving as the anode of the organic light-emitting element 100 and the second electrode 180, holes injected from the hybrid electrode having a high work function and high conductivity 1 serving as the anode move to the light-emitting layer 150 through the hole transport layer 140, and electrons injected from the second electrode 180 move to the light-emitting layer 150 through the electron transport layer 160 and the electron injection layer 170. Carriers such as the holes and the electrons are recombined in the light-emitting layer 150 and generate excitons. The excitons are changed from excited states to ground states, and thus light is generated.

As the substrate 110, a substrate used in a general semiconductor process may be used. For example, the substrate may include glass, sapphire, silicone, a silicon oxide, a metal foil (for example, a copper foil and an aluminum foil), a steel substrate (for example, stainless steel), a metal oxide, a polymer substrate and combinations of two or more thereof. Examples of the metal oxide may include an aluminum oxide, a molybdenum oxide, an indium oxide, a tin oxide and an indium tin oxide. Examples of the polymer substrate may include a kapton foil, a polyethersulfone (PES), a polyacrylate (PAR), a polyetherimide (PEI), a polyethylene napthalate (PEN), a polyethyleneterepthalate (PET), a polyphenylene sulfide (PPS), a polyallylate, a polyimide, a polycarbonate (PC), a cellulose triacetate (TAC), and a cellulose acetate propinonate (CAP), but the present invention is not limited thereto.

For example, the substrate 110 may be the polymer substrate, but the present invention is not limited thereto.

The hybrid electrode having a high work function and high conductivity 1 may be formed on the substrate 110.

The work function-tuning layer 130 includes a material having low surface energy. When the material having low surface energy is included, a work function of a second surface 130B that is included in the work function-tuning layer 130 and faces the hole transport layer 140 may be 5.0 eV or more. For example, in the hybrid electrode, the work function measured in the second surface 130B of the work function-tuning layer 130 may be 5.0 eV to 6.5 eV, but the present invention is not limited thereto.

In this specification, the material having low surface energy is a material that can form a film having low surface energy, and specifically, refers to a material having lower surface energy than a conductive material to be described (included in the conductivity-tuning layer).

The material having low surface energy is a material including at least one fluorine atom and may have greater hydrophobicity than a conductive polymer. Also, the material having low surface energy may be a material that can provide a greater work function than that of the conductive material. For example, the material having low surface energy may be a material enabling a thin film made of the material having low surface energy and having a thickness of 100 nm to have a surface energy of 30 mN/m or less and to have a conductivity of 10⁻¹ to 10⁻¹⁵ S/cm.

The material having low surface energy may be a material having a solubility of 90% or more, for example, a solubility of 95% or more, with respect to a polar solvent. Examples of the polar solvent may include water, an alcohol (such as methanol, ethanol, n-propanol, 2-propanol, and n-butanol), ethylene glycol, glycerol dimethylformamide (DMF), dimethylsulfoxide (DMSO), and acetone, but the present invention is not limited thereto.

The material having low surface energy may be a material which includes at least one fluorine atom. For example, the material having low surface energy may be a fluorinated polymer or a fluorinated oligomer including at least one fluorine atom.

For example, the material having low surface energy may be an ionomer which includes one or more repeating units of the following Chemical Formulae 2 to 13.

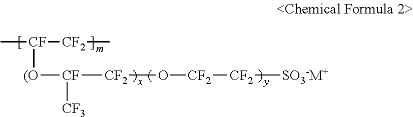

In Chemical Formula 2, m is a number of 1 to Ser. No. 10/000,000, x and y each independently represent a number of 0 to 10, and M⁺ represents Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; n is an integer of 0 to 50).

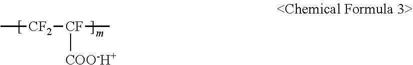

In Chemical Formula 3, m is a number of 1 to Ser. No. 10/000,000.

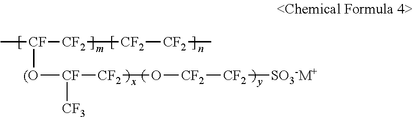

In Chemical Formula 4, m and n satisfy 0<m≦10,000,000, and 0≦n<10,000,000, x and y each independently represent a number of 0 to 20, and M⁺ represents Na⁺, K⁺, Li⁺, H⁺, CH₃(CH₂)₁NH₃⁺ (n is an integer of 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; n is an integer of 0 to 50).

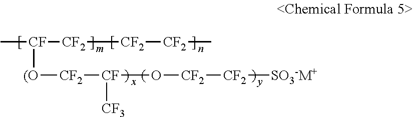

In Chemical Formula 5, m and n satisfy 0<m≦10,000,000, and 0≦n<10,000,000, x and y each independently represent a number of 0 to 20, and M⁺ represents Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅OH⁺, CH₃OH⁺, RCHO⁺ (R is CH₃(CH₂)ₙ—; n is an integer of 0 to 50).

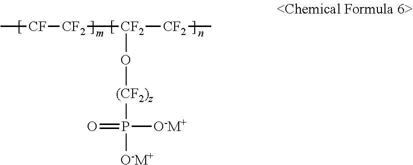

In Chemical Formula 6, m and n satisfy 0<m≦10,000,000, and 0≦n<10,000,000, z is a number of 0 to 20, and M⁺ represents Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; n is an integer of 0 to 50);

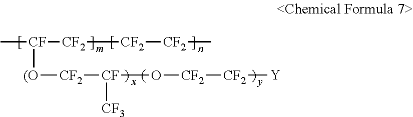

In Chemical Formula 7, m and n satisfy 0<m≦10,000,000, and 0≦n<10,000,000, x and y each independently represent a number of 0 to 20, Y is one selected from among —COO⁻M⁺, —SO₃⁻NHSO₂CF3⁺, and —PO₃²⁻(M⁺)₂, and M⁺ represents Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; n is an integer of 0 to 50).

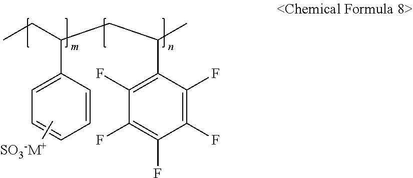

In Chemical Formula 8, m and n satisfy 0<m≦10,000,000 and 0≦n<10,000,000, and M⁺ represents Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅HO⁺, CH₃HO⁺, or RCHO⁺ (R is CH₃(CH₂)ₙ—; n is an integer of 0 to 50).

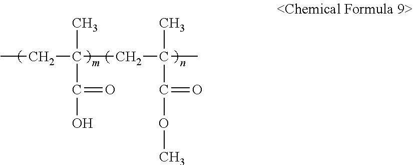

In Chemical Formula 9, m and n satisfy 0<m≦10,000,000, and 0≦n<10,000,000;

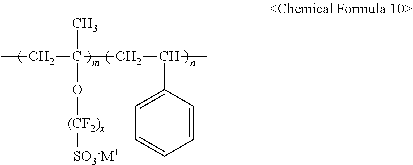

In Chemical Formula 10, m and n satisfy 0<m≦10,000,000, and 0≦n<10,000,000, x is a number of 0 to 20, and M⁺ represents Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; n is an integer of 0 to 50).

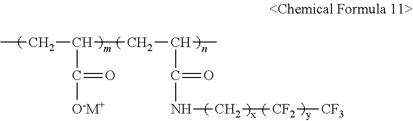

In Chemical Formula 11, m and n satisfy 0<m≦10,000,000, and 0≦n<10,000,000, x and y each independently represent a number of 0 to 20, and M⁺ represents Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; n is an integer of 0 to 50).

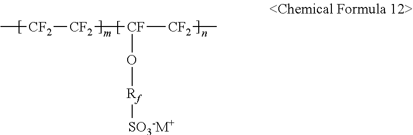

In Chemical Formula 12, m and n satisfy 0≦m<10,000,000, and 0<n≦10,000,000, R_{f}=—(CF₂)_{z}— (z is an integer of 1 to 50, except 2), —(CF₂CF₂O)_{z}CF₂CF₂— (z is an integer of 1 to 50), —(CF₂CF₂CF₂O)_{z}CF₂CF₂— (z is an integer of 1 to 50), and M⁺ represents Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; n is an integer of 0 to 50);

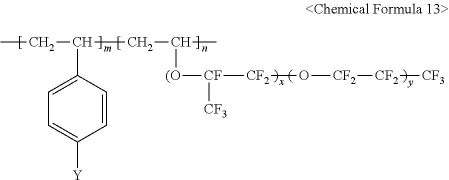

In Chemical Formula 13, m and n satisfy 0≦m<10,000,000, and 0<n≦10,000,000, x and y each independently represent a number of 0 to 20, Y each independently represent one selected from among —SO₃⁻M⁺, —COO⁻M⁺, —SO₃⁻NHSO₂CF3⁺, and —PO₃²⁻(M⁺)₂, and M⁺ represents Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; n is an integer of 0 to 50).

Alternatively, the material having low surface energy may be a fluorinated ionomer having a structure of the following Chemical Formulae 14 to 19.

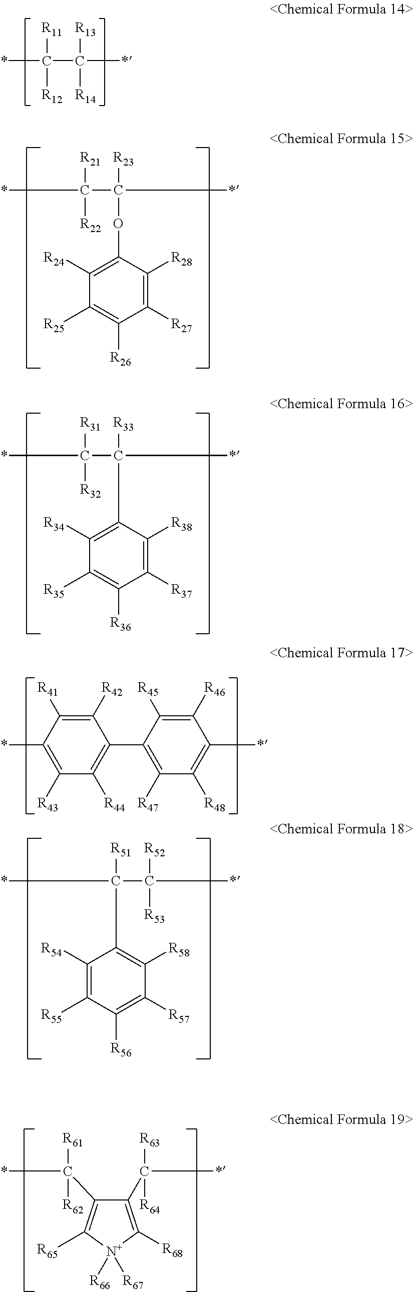

### In Chemical Formulae 14 to 19,

R₁₁ to R₁₄, R₂₁ to R₂₈, R₃₁ to R₃₈, R₄₁ to R₄₈, R₅₁ to R₅₈ and R₆₁ to R₆₈ each are independently selected from among hydrogen, —F, a C₁-C₂₀ alkyl group, a C₁-C₂₀ alkoxy group, a C₁-C₂₀ alkyl group substituted with at least one —F, a C₁-C₂₀ alkoxy group substituted with at least one —F, Q₁, —O—(CF₂CF(CF₃)—O)ₙ—(CF₂)ₘ-Q₂ (here, n and m each independently represent an integer of 0 to 20, and n+m is 1 or more) and —(OCF₂CF₂)ₓ-Q₃ (here, x is an integer of 1 to 20), Q₁ to Q₃ represent an ionic group, the ionic group includes an anionic group and a cationic group, the anionic group is selected from among PO₃²⁻, SO₃⁻, COO⁻, I⁻, CH₃COO⁻ and BO₂²⁻, the cationic group includes at least one type of a metal ion and an organic ion, the metal ion is selected from among Na⁺, K⁺, Li⁺, Mg⁺², Zn⁺² and Al⁺³, and the organic ion is selected from among H⁺, CH₃(CH₂)ₙ₁NH₃⁺ (here, n1 is an integer of 0 to 50), NH₄⁺, NH₂⁺, NHSO₂CF₃⁺, CHO⁺, C₂H₅OH⁺, CH₃OH⁺ and RCHO⁺ (here, R is CH₃(CH₂)ₙ₂—, and n2 is an integer of 0 to 50),

at least one of R₁₁ to R₁₄, at least one of R₂₁ to R₂₈, at least one of R₃₁ to R₃₈, at least one of R₄₁ to R₄₈, at least one of R₅₁ to R₅₈ and at least one of R₆₁ to R₆₈ are selected from among —F, a C₁-C₂₀ alkyl group substituted with at least one —F, a C₁-C₂₀ alkoxy group substituted with at least one —F, —O—(CF₂CF(CF₃)—O)ₙ—(CF₂)ₘ-Q₂ and —(OCF₂CF₂)ₓ-Q₃.

Meanwhile, the material having low surface energy may be a fluorinated oligomer represented by the following Chemical Formula 20.

X-M^{f}ₙ-M^{h}ₘ-M^{a}ᵣ-Gₚ <Chemical Formula 20>

In Chemical Formula 20,

X represents an end group;

M^{f} represents a unit derived from a fluorinated monomer obtained from a condensation reaction of a perfluoropolyether alcohol, a polyisocyanate and an isocyanate-reactive non-fluorinated monomer;

M^{h} represents a unit derived from a non-fluorinated monomer;

M^{a} represents a unit including a silyl group represented as Si(Y₄)(Y₅)(Y₆);

Y₄, Y₅ and Y₆ each independently represent a substituted or unsubstituted C₁-C₂₀ alkyl group, a substituted or unsubstituted C₆-C₃₀ aryl group or a hydrolyzable substituent, and at least one of Y₄, Y₅ and Y₆ represents the hydrolyzable substituent; G represents a monohydric organic group including a residue of a chain transfer agent;

n is a number of 1 to 100;

m is a number of 0 to 100;

r is a number of 0 to 100;

n+m+r is at least 2.

For example, in Chemical Formula 20, X may be a halogen atom, M^{f} may be a fluorinated C₁-C₁₀ alkylene group, M^{h} may be a C₂-C₁₀ alkylene group, Y₄, Y₅ and Y₆ may each independently represent a halogen atom (such as Br, Cl, or F), and p may be 0. For example, a fluorinated silane material represented by Chemical Formula 20 may be CF₃CH₂CH₂SiCl₃, but the present invention is not limited thereto.

In this specification, a specific example of the unsubstituted alkyl group may include linear or branched methyl, ethyl, propyl, isobutyl, sec-butyl, tert-butyl, pentyl, iso-amyl, hexyl groups and the like. One or more hydrogen atoms included in the alkyl group may be substituted with a halogen atom, a hydroxy group, a nitro group, a cyano group, a substituted or unsubstituted amino group (—NH₂, —NH(R), —N(R′)(R″), R′ and R″ each independently represent an alkyl group having 1 to 10 carbon atoms), an amidino group, hydrazine, a hydrazine group, a carboxyl group, a sulfonic acid group, a phosphate group, a C₁-C₂₀ alkyl group, a C₁-C₂₀ halogenated alkyl group, a C₁-C₂₀ alkenyl group, a C₁-C₂₀ alkynyl group, a C₁-C₂₀ heteroalkyl group, a C₆-C₂₀ aryl group, a C₆-C₂₀ arylalkyl group, a C₆-C₂₀ heteroaryl group, or a C₆-C₂₀ heteroarylalkyl group.

In this specification, the heteroalkyl group refers to a group in which one or more carbon atoms, and preferably 1 to 5 carbon atoms, of a main chain of the alkyl group is substituted with a hetero atom such as an oxygen atom, a sulfur atom, a nitrogen atom, or a phosphorus atom.

In this specification, the aryl group refers to a carbocycle aromatic system including one or more aromatic rings. The rings may be attached or fused together using a pendant method. A specific example of the aryl group may include an aromatic group such as phenyl, naphthyl, and tetrahydronaphthyl groups. One or more hydrogen atoms of the aryl group may be substituted with the same substituent as that of the alkyl group.

In this specification, the heteroaryl group refers to an aromatic ring system that includes 1, 2 or 3 hetero atoms selected from among N, O, P and S, and the remaining 5 to 30 ring atoms are carbon. The rings may be attached or fused together using a pendant method. Also, one or more hydrogen atoms of the heteroaryl group may be substituted with the same substituent as that of the alkyl group.

In this specification, the alkoxy group refers to a radical-O-alkyl. In this case, the alkly is the same as defined above. A specific example may include methoxy, ethoxy, propoxy, iso-butyloxy, sec-butyloxy, pentyloxy, iso-amyloxy, hexyloxy and the like. One or more hydrogen atoms of the alkoxy group may be substituted with the same substituent as that of the alkyl group

A heteroalkoxy group that is a substituent used in the present invention essentially has the meaning of the alkoxy except that one or more hetero atoms, for example, oxygen, sulfur or nitrogen, may be present in an alkyl chain, and includes, for example, CH₃CH₂OCH₂CH₂O—, C₄H₉OCH₂CH₂OCH₂CH₂O— and CH₃O(CH₂CH₂O)ₙH.

In this specification, the arylalkyl group refers to a group in which some of the hydrogen atoms in the aryl group as defined above are substituted with a lower alkyl, for example, a radical such as methyl, ethyl, or propyl. Benzyl or phenylethyl is exemplified. One or more hydrogen atoms of the arylalkyl group may be substituted with the same substituent as that of the alkyl group.

In this specification, the heteroarylalkyl group refers to a group in which some of the hydrogen atoms in the heteroaryl group are substituted with a lower alkyl group. Definition of heteroaryl in the heteroarylalkyl group is the same as described above. One or more hydrogen atoms of the heteroarylalkyl group may be substituted with the same substituent as that of the alkyl group.

In this specification, the aryloxy group refers to a radical-O-aryl. In this case, the aryl is the same as defined above. As a specific example, phenoxy, naphthoxy, anthracenyloxy, phenanthrenyloxy, fluorenyloxy, or indenyloxy may be exemplified. One or more hydrogen atoms of the aryloxy group may be substituted with the same substituent as that of the alkyl group.

In this specification, the heteroaryloxy group refers to a radical —O-heteroaryl. In this case, the heteroaryl is the same as defined above.

In this specification, specific examples of the heteroaryloxy group include benzyloxy and phenylethyloxy groups. One or more hydrogen atoms of the heteroaryloxy group may be substituted with the same substituent as that of the alkyl group.

In this specification, a cycloalkyl group refers to a monohydric monocyclic system having 5 to 30 carbon atoms. At least one hydrogen atom of the cycloalkyl group may be substituted with the same substituent as that of the alkyl group.

In this specification, a heterocycloalkyl group refers to a monohydric monocyclic system that includes 1, 2 or 3 hetero atoms selected from among N, O, P and S, and the remaining 5 to 30 ring atoms are carbon. One or more hydrogen atoms of the cycloalkyl group may be substituted with the same substituent as that of the alkyl group.

In this specification, an alkylester group refers to a functional group in which an alkyl group and an ester group are combined. In this case, the alkyl group is the same as defined above.

In this specification, a heteroalkylester group refers to a functional group in which a heteroalkyl group and an ester group are combined. The heteroalkyl group is the same as defined above.

In this specification, an arylester group refers to a functional group in which an aryl group and an ester group are combined. In this case, the aryl group is the same as defined above.

In this specification, a heteroarylester group refers to a functional group in which a heteroaryl group and an ester group are combined. In this case, the heteroaryl group is the same as defined above.

An amino group used in the present invention refers to —NH₂, —NH(R) or —N(R′)(R″). R′ and R″ each independently represent an alkyl group having 1 to 10 carbon atoms.

In this specification, a halogen refers to fluorine, chlorine, bromine, iodine, or astatine, and fluorine is particularly preferable among these.

The conductivity-tuning layer 120 includes at least one of a conductive polymer, a metallic carbon nanotube, a graphene, a reduced graphene oxide, a metallic nanowire, a semiconductor nanowire, a metallic grid, a metallic nanodot and a conductive oxide, and does not include the material having low surface energy.

The conductivity-tuning layer 120 mainly improves conductivity of the hybrid electrode having a high work function and high conductivity 1, and additionally adjusts scattering, reflection, and absorption to improve optical extraction (in an OLED) or light incidence (in a solar cell), or provides flexibility to improve mechanical strength.

The conductivity-tuning layer 120 is in contact with a first surface 130A of the work function-tuning layer 130.

For example, the conductive polymer may include a polythiophene, a polyaniline, a polypyrrole, a polystyrene, a sulfonated polystyrene, a poly(3,4-ethylenedioxythiophene), a self-doped conductive polymer, derivatives thereof or combinations thereof. The derivatives may refer to further inclusion of various sulfonic acids or the like.

For example, the conductive polymer may include a polyaniline/dodecylbenzenesulfonic acid (Pani:DBSA, refer to the following chemical formula), a poly(3,4-ethylenedioxythiophene)/poly(4-styrenesulfonate) (PEDOT:PSS, refer to the following chemical formula), polyaniline/camphor sulfonic acid (Pani:CSA), or a polyaniline/poly(4-styrenesulfonate (PANI:PSS), but the present invention is not limited thereto.

For example, a specific example of the conductive polymer is as follows, but the present invention is not limited thereto:

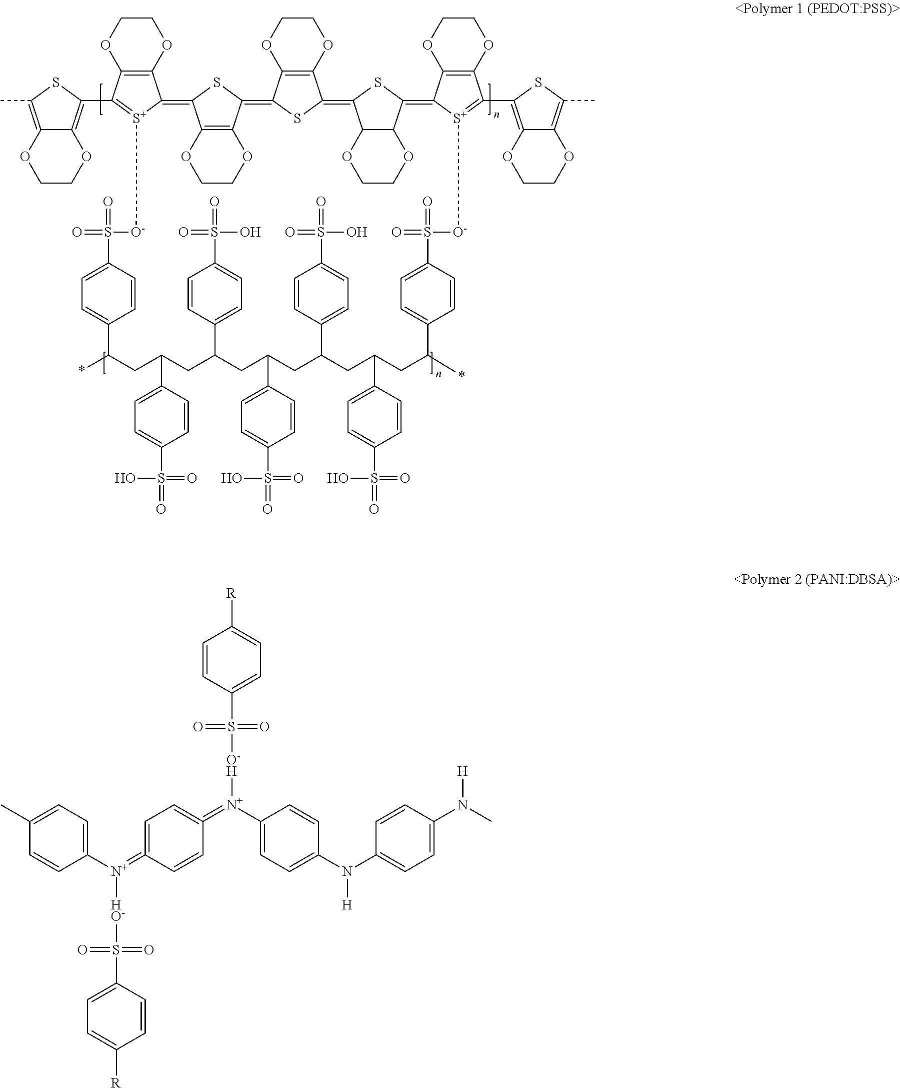

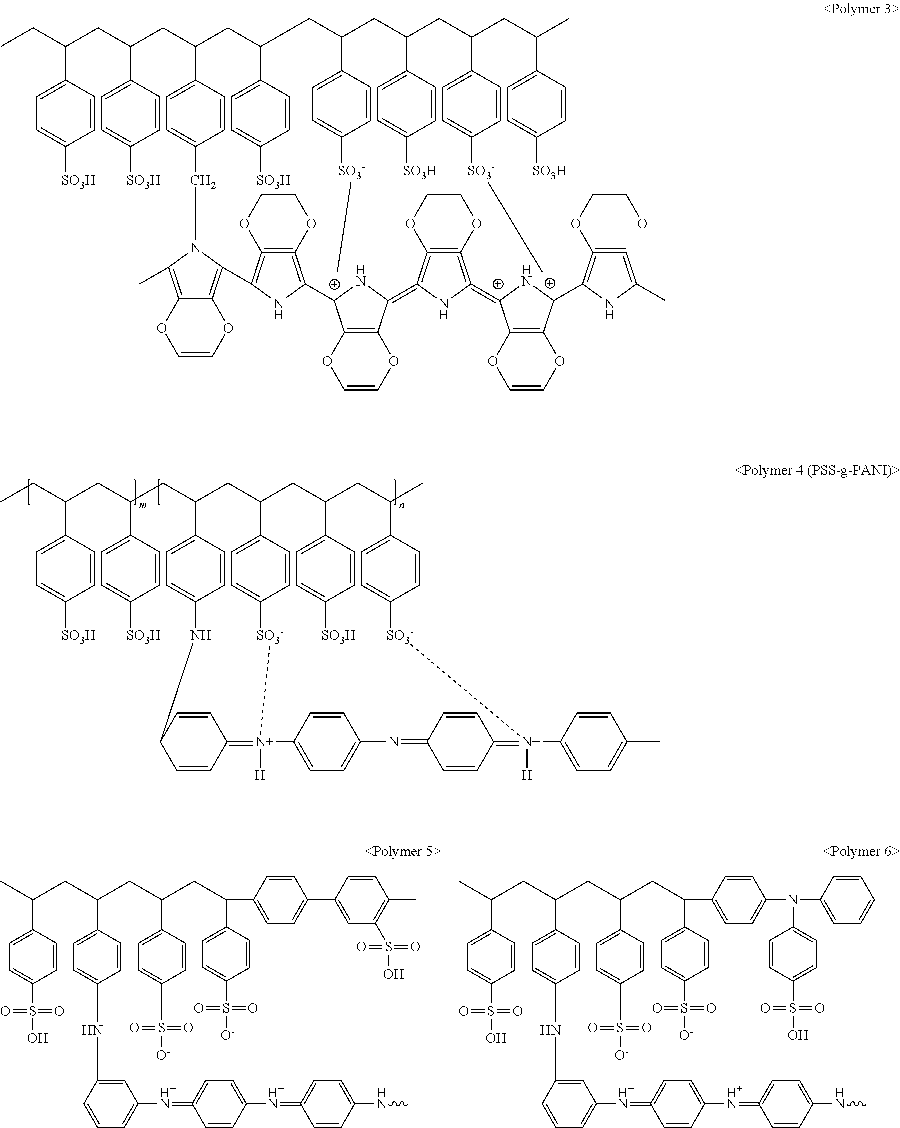

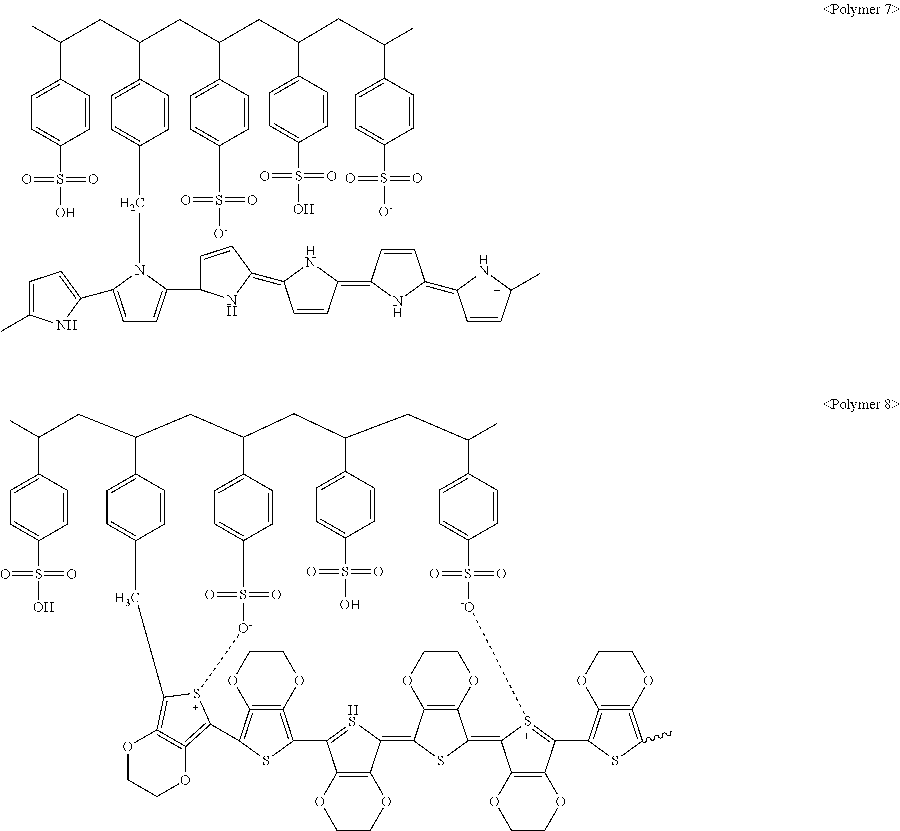

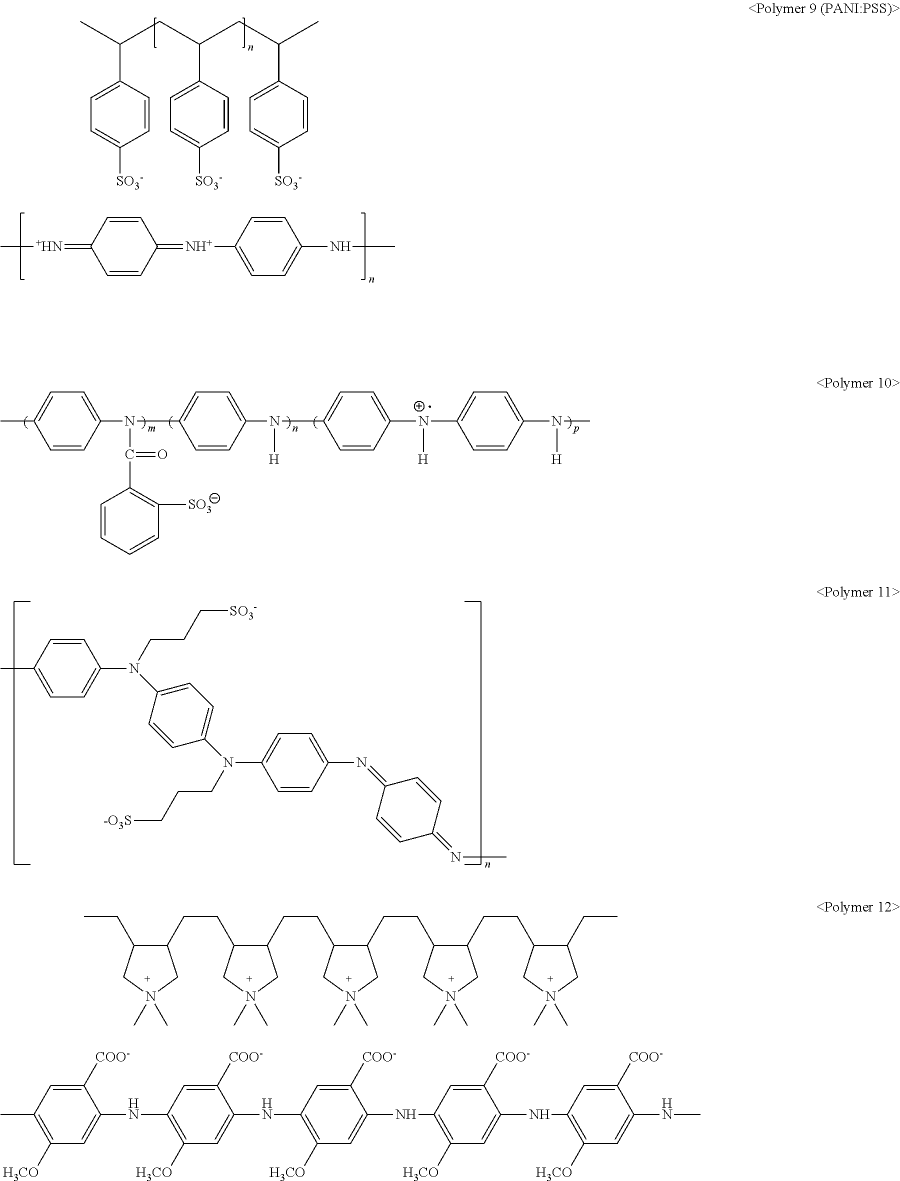

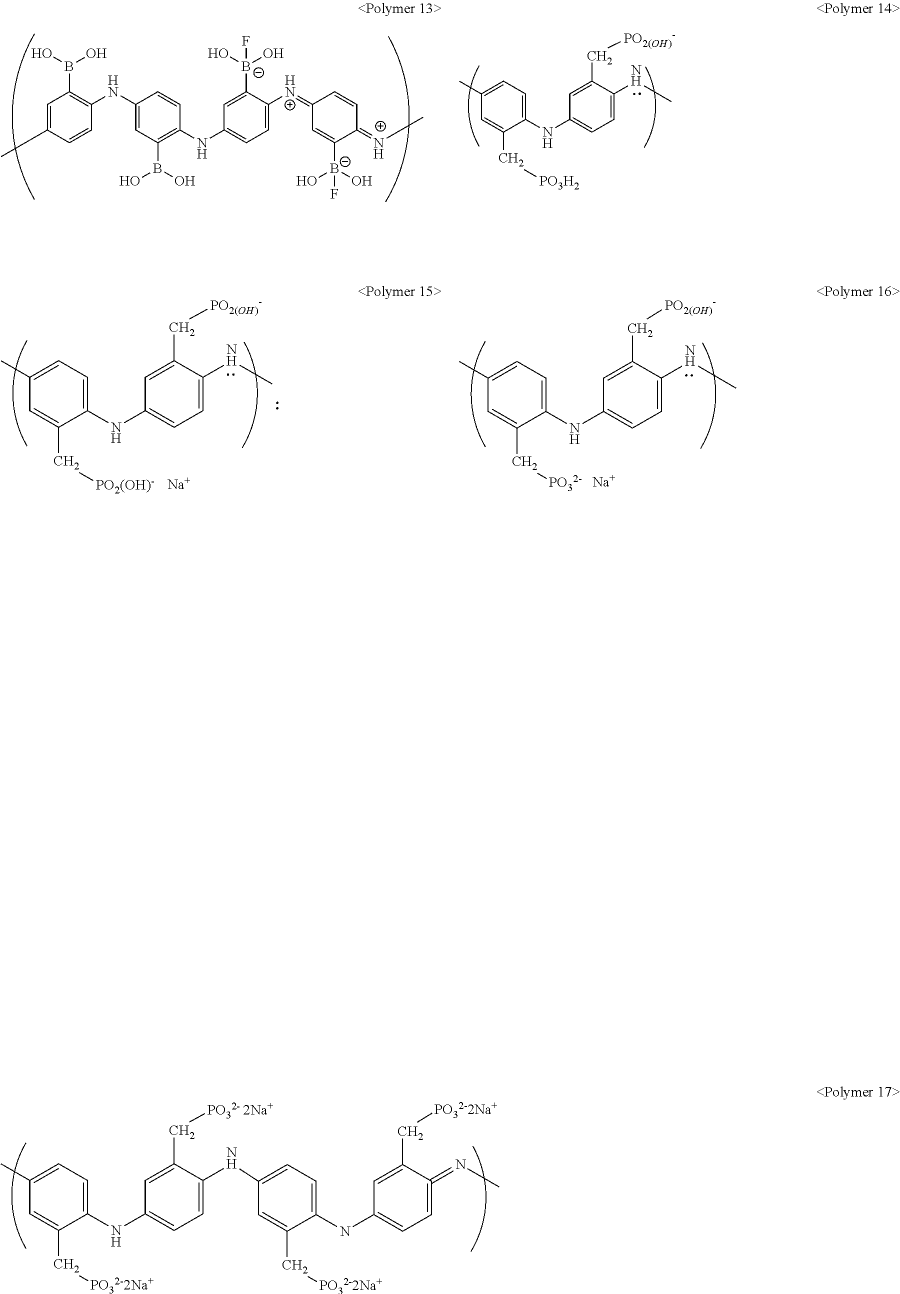

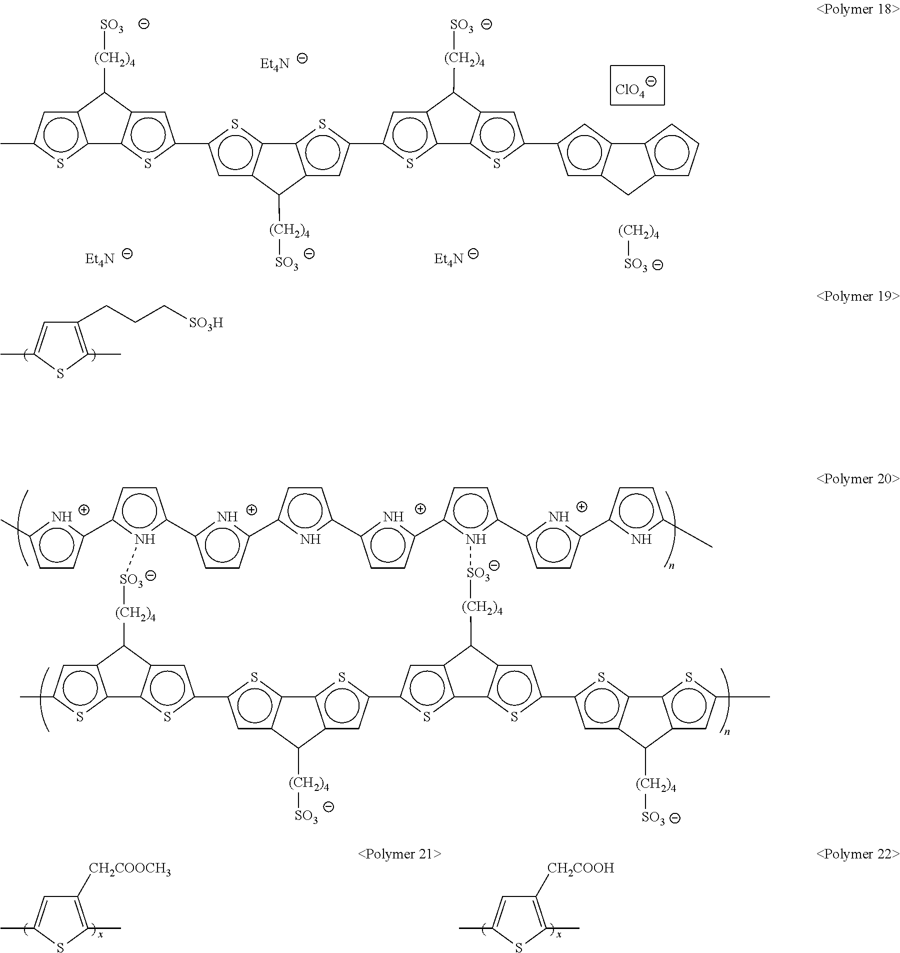

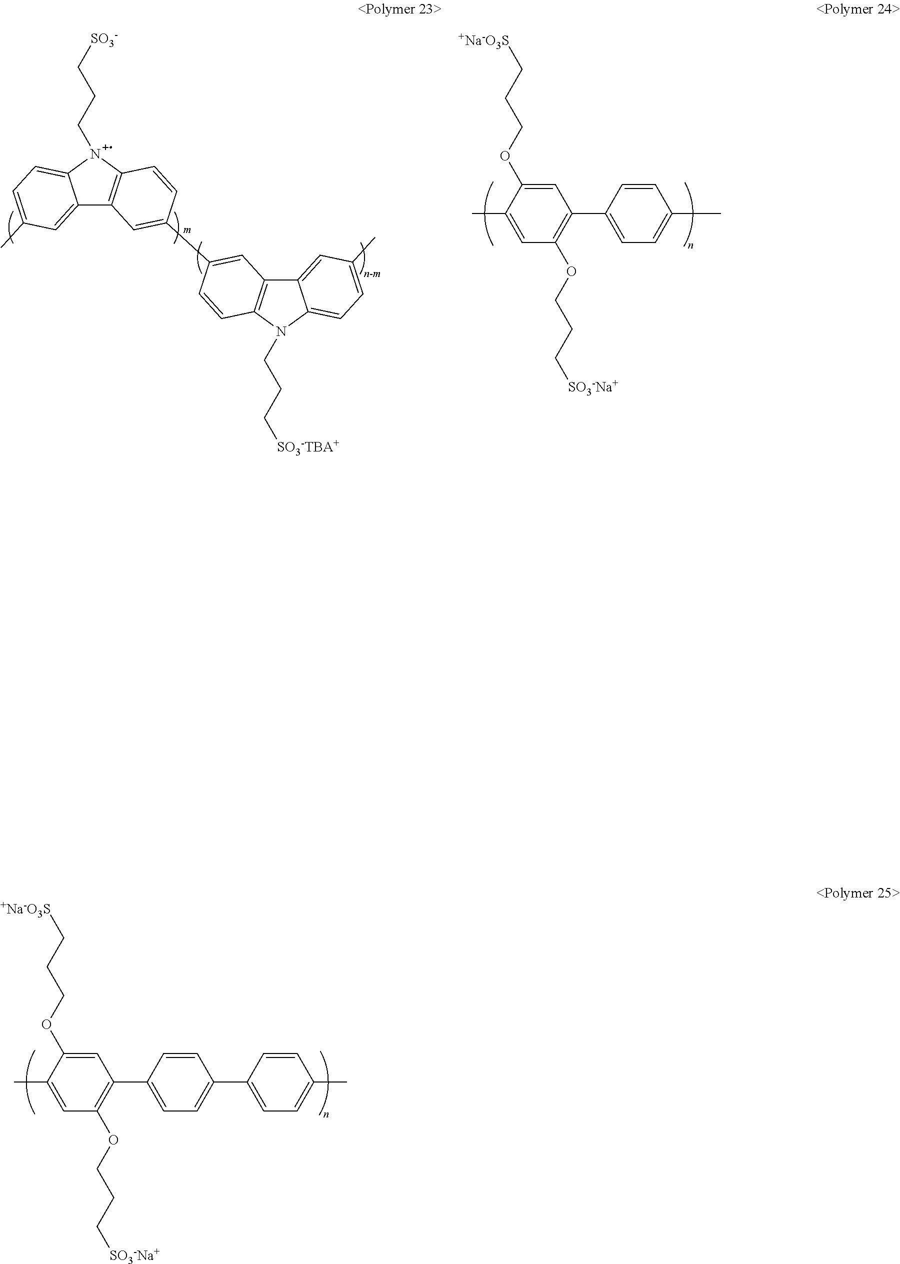

The metallic carbon nanotube may be a material of a purified metallic carbon nanotube itself, or a carbon nanotube in which metal particles (for example, Ag, Au, Cu, or Pt particles) are attached to an inner wall and/or an outer wall of the carbon nanotube.

The graphene may have a single-layer graphene having a thickness of about 0.34 nm, a few-layer graphene having a structure in which 2 to 10 single-layer graphenes are laminated, or a multilayer graphene structure in which more single-layer graphenes than that of the few-layer graphene are laminated.

The metallic nanowire and the semiconductor nanowire may be selected from among, for example, Ag, Au, Cu, Pt NiSiₓ(Nickel Silicide) nanowires and a composite (for example, an alloy or a core-shell structure) nanowire of two or more thereof, but the present invention is not limited thereto.

Alternatively, the semiconductor nanowire may be selected from among a Si nanowire doped with Si, Ge, B or N, a Ge nanowire doped with B or N, and a composite (for example, an alloy or a core-shell structure) of two or more thereof, but the present invention is not limited thereto.

The metallic nanowire and the semiconductor nanowire may have a diameter of 5 nm to 100 nm or less and a length of 500 nm to 100 μm. These may be variously selected according to a method of manufacturing the metallic nanowire and the semiconductor nanowire.

In the metallic grid, metal lines which have a reticulated mesh shape are formed using Ag, Au, Cu, Al, Pt or an alloy thereof, a line width is 100 nm to 100 μm, and a length has no limitation. The metallic grid may be formed to protrude from the substrate, or may be inserted into the substrate to form a depression type substrate.

The metallic nanodot may be selected from among Ag, Au, Cu, Pt and a composite (for example, an alloy or a core-shell structure) nanodot of two or more thereof, but the present invention is not limited thereto.

At least one moiety (here, Z₁₀₀, Z₁₀₁, Z₁₀₂, and Z₁₀₃ each independently represent a hydrogen atom, a halogen atom, a substituted or unsubstituted C₁-C₂₀ alkyl group or a substituted or unsubstituted C₁-C₂₀ alkoxy group) represented as —S(Z₁₀₀) and —Si(Z₁₀₁)(Z₁₀₂)(Z₁₀₃) may be combined with surfaces of the metallic nanowire, the semiconductor nanowire and the metallic nanodot. The at least one moiety represented as —S(Z₁₀₀) and —Si(Z₁₀₁)(Z₁₀₂)(Z₁₀₃) is a self-assembled moiety. Through the moiety, it is possible to reinforce cohesion among the metallic nanowire, the semiconductor nanowire and the metallic nanodot or a binding force of a substrate 210 with the metallic nanowire, the semiconductor nanowire and the metallic nanodot. Therefore, it is possible to manufacture the hybrid electrode having a high work function and high conductivity 1 which has further improved electrical characteristics and mechanical strength.

The conductive oxide may be any of an indium tin oxide (ITO), an indium zinc oxide (IZO), SnO₂ and InO₂.

When the hybrid electrode having a high work function and high conductivity 1 is used as a transparent electrode, the work function-tuning layer 130 of the hybrid electrode having a high work function and high conductivity 1 may have a thickness of 20 nm to 500 nm, for example, 50 nm to 200 nm. When the thickness of the work function-tuning layer 130 satisfies the above range, it is possible to provide excellent work function characteristics, transmittance and flexibility characteristics.

Conductivity of the hybrid electrode having a high work function and high conductivity 1 may be 1 S/cm or more (when a thickness of the hybrid electrode having a high work function and high conductivity 1 is 100 nm).

The hybrid electrode having a high work function and high conductivity 1 described above may be formed by the formation of the conductivity-tuning layer 120 on the substrate 110, a mixture including the material having low surface energy and a first solvent is then provided on the conductivity-tuning layer 120, heat treatment is then performed thereon, and the work function-tuning layer 130 is formed.

First, the conductivity-tuning layer 120 is formed on the substrate 110.

According to an implementation example, at least one of the conductive polymer, the metallic carbon nanotube, the graphene, the reduced graphene oxide, the metallic nanowire, the metallic grid, the carbon nanodot, the semiconductor nanowire and the metallic nanodot is directly provided on the substrate 110 using a spin coating method, a casting method, a Langmuir-Blodgett (LB) method, an ink jet printing method, a nozzle printing method, a slot-die coating method, a doctor blade coating method, a screen printing method, a dip coating method, a gravure printing method, a reverse-offset printing method, a physical transfer method, a spray coating method, a chemical vapor deposition method, a thermal evaporation method or the like is directly provided on the substrate 110 which forms the conductivity-tuning layer.

According to another implementation example, the conductivity-tuning layer 120 may be formed by an application of a mixture including i) at least one of the conductive polymer, the metallic carbon nanotube, the graphene, the reduced graphene oxide, the metallic nanowire, the metallic grid, the carbon nanodot, the semiconductor nanowire and the metallic nanodot and ii) a second solvent onto the substrate, heat treatment is then performed thereon, and the second solvent is removed. As an example of the second solvent, refer to an example of the first solvent to be described below.

According to still another implementation example, when the conductivity-tuning layer 120 includes the graphene, a graphene sheet is physically transferred onto the substrate 110 for formation.

According to yet another implementation example, when the conductivity-tuning layer 120 includes the metallic carbon nanotube, the metallic carbon nanotube may be grown on the substrate 110, or a carbon nanotube dispersed in a solvent may be formed by a solution-based printing method (for example, a spray coating method, a spin coating method, a dip coating method, a gravure coating method, a reverse-offset coating method, a screen printing method, or a slot-die coating method).

According to yet another implementation example, when the conductivity-tuning layer 120 includes a metallic grid, a metal is vacuum-deposited on the substrate 110, a metal film is formed and then patterning is performed in several mesh shapes by photolithography, or metal precursors or metal particles are dispersed in a solvent, and a printing method (for example, a spray coating method, a spin coating method, a dip coating method, a gravure coating method, a reverse-offset coating method, a screen printing method, and a slot-die coating method) is used for formation.

Next, the above-described mixture including the material having low surface energy and the first solvent is provided onto the conductivity-tuning layer 120. For descriptions of the material having low surface energy refer to the above descriptions. The first solvent may be a solvent that has miscibility with the material having low surface energy and is easily removed by heating or the like. The first solvent may be the polar solvent, for example, water, an alcohol (such as methanol, ethanol, n-propanol, 2-propanol, or n-butanol), a formic acid, nitromethane, an acetic acid, ethylene glycol, glycerol, n-Methyl-2-Pyrrolidone (NMP), N-dimethylacetamide, dimethylformamide (DMF), dimethyl sulfoxide (DMSO), tetrahydrofuran (THF), ethyl acetate (EtOAc), acetone, acetonitrile (MeCN) or the like. Meanwhile, when the first solvent is selected, a co-solvent may be used. For example, as the first solvent, a mixture of water and an alcohol may be used.

The organic light-emitting element 100 may include no hole injection layer. Thin film conductivity of a hole injection layer of the related art formed of a conductive polymer composition such as poly(3,4-ethylene dioxythiophene):poly(styrene sulfonate)(PEDOT:PSS) and polyaniline:poly(styrene sulfonate) (PANI:PSS) is about 10⁻⁶ S/cm to 10⁻² S/cm. For example, PEDOT:PSS of CLEVIOUS™ PVPAI4083 (Heraeous, previous H.C. Starck) has a conductivity of 10⁻³ S/cm, and PEDOT:PSS of CLEVIOUS™ PVPCH8000 (Heraeous, previous H.C. Starck) has a conductivity of 10⁻⁶ S/cm. However, in order to use the conductive polymer as an electrode material, the conductive polymer needs to have a conductivity of at least 0.1 S/cm or more. Therefore, it is difficult to use PEDOT:PSS, PANI:PSS or the like which are used in the hole injection layer of the related art as the electrode material. Also, it is difficult to use the conductive polymer having a conductivity of 0.1 S/cm or more of the present invention as a material of the hole injection layer. This is because, when the conductive polymer is used as the material of the hole injection layer, crosstalk may occur between pixels of the organic light-emitting element. Therefore, the conductive polymer for forming the hole injection layer of the related art was selected from among materials that have a conductivity of 10⁻² S/cm or less, have a higher work function than an ITO of the related art, and facilitate an injection of hole.

FIG. 2 is a diagram schematically illustrating a work function relation among the conductivity-tuning layer 120, the work function-tuning layer 130 and the hole transport layer 140 of the hybrid electrode having a high work function and high conductivity 1.

In FIG. 2, the work function increases as vacuum level goes down. In FIG. 2, when a material such as a graphene sheet or a metallic grid is used as the conductivity-tuning layer 120, the work function-tuning layer 130 increases a surface work function, and a change in an energy level having a step-like form is observed for each layer as illustrated in FIG. 2.

Therefore, in FIG. 2, when the work function-tuning layer 130 and the conductivity-tuning layer 120 are not mixed, the work function-tuning layer 130A and the upper surface 130B have the same ionization energy. When a work function-tuning layer dispersed in a solvent is applied onto a conductive layer-tuning layer, since a lower layer is partially dissolved, dispersed, and mixed, one layer rather than two layers may be finally formed. Therefore, a change in an electronic energy level having a gradient may be generated.

As described above, when the material such as a graphene sheet or a metallic grid that is not melted or dispersed in the solvent is used as the conductivity-tuning layer 120, the first surface 130A of the work function-tuning layer 130 has a work function of Y₁ eV, and the second surface 130B has a work function of Y₂ eV, and Y₁═Y₂.

As described above, when the conductive polymer that may be melted or dispersed in the solvent is used as the conductivity-tuning layer 120, a work function of the work function-tuning layer 130 may be a variable having a gradient that gradually increases in a direction from the first surface 130A of the work function-tuning layer 130 to the second surface 130B. In the work function-tuning layer 130, the first surface 130A has a work function of Y₁ eV, the second surface 130B has a work function of Y₂ eV, and Y₁<Y₂.

Therefore, when there is no hole injection layer between the hybrid electrode having a high work function and high conductivity 1 serving as the anode and the hole transport layer 140, it is possible to increase efficiency of hole movement from the hybrid electrode having a high work function and high conductivity 1 to the hole transport layer 140. That is, it may be interpreted that the hybrid electrode having a high work function and high conductivity 1 serves as the anode and the hole injection layer of the related art. Therefore, when the hole injection layer is not formed, the organic light-emitting element 100 including the hybrid electrode having a high work function and high conductivity 1 which serves as the anode may have excellent efficiency, brightness and lifespan characteristics. Therefore, it is possible to decrease a manufacturing cost of the organic light-emitting element 100.

The hole transport layer 140 may have a work function of Z eV. Z may be a real number of 5.2 to 5.6, but the present invention is not limited thereto.

When a material such as a graphene sheet, a metallic grid, or a conductive oxide thin film that is not dispersed in the solvent is used as the conductivity-tuning layer 120, a change in an energy level having a step-like form is observed for each layer as illustrated in FIG. 2.

Therefore, in FIG. 2, when there is no mixing in the work function-tuning layer 130, the first surface 130A and the second surface 130B of the work function-tuning layer 130 have the same ionization energy or work function (Y₁═Y₂). When the conductivity-tuning layer of the hybrid electrode having a high work function and high conductivity 1 is the conductive polymer that may be melted or dispersed in the solvent, a work function value Y₁ of the first surface 130A of the work function-tuning layer 130 may be in a range of 4.6 to 5.2, for example, 4.7 to 4.9. A work function value Y₂ of the second surface 130B of the work function-tuning layer 130 of the hybrid electrode having a high work function and high conductivity 1 may be the same as or lower than a work function of the material having low surface energy included in the work function-tuning layer 130. For example, Y₂ may be in a range of 5.0 to 6.5, for example, 5.3 to 6.2, but the present invention is not limited thereto.

Since the organic light-emitting element 100 has no hole injection layer, the second surface 130B of the work function-tuning layer 130 of the hybrid electrode having a high work function and high conductivity 1 which serves as the anode may be in contact with the hole transport layer 140.

The hole transport layer 140 may be formed by a method that is arbitrarily selected from among various known methods such as a vacuum deposition method, a spin coating method, a casting method, and an LB method. In this case, when the vacuum deposition method is selected, deposition conditions are changed according to a target compound, a structure of a target layer, thermal characteristics and the like. For example, the conditions may be selected within a deposition temperature range of 100° C. to 500° C., a vacuum degree range of 10⁻¹⁰ to 10⁻³ torr, and a deposition rate range of 0.01 to 100 Å/sec. Meanwhile, when the spin coating method is selected, coating conditions may be changed according to a target compound, a structure of a target layer and thermal characteristics, but may be selected within a coating rate range of 2000 rpm to 5000 rpm, and a heat treatment temperature range of 80° C. to 200° C. (a heat treatment temperature for removing the solvent after coating).

A material of the hole transport layer 140 may be selected from among materials that can better perform hole transport rather than hole injection. The hole transport layer 140 may be formed using a known hole transport material, and may be, for example, an amine-based material having a condensed aromatic ring or a triphenylamine-based material.

More specifically, examples of the hole transporting material may include 1,3-bis(carbazol-9-yl)benzene (MCP), 1,3,5-tris(carbazol-9-yl)benzene (TCP), 4,4′,4″-tris(carbazol-9-yl)triphenylamine (TCTA), 4,4′-bis(carbazol-9-yl)biphenyl (CBP), N,N′-bis(naphthalen-1-yl)-N,N′-bis(phenyl)-benzidine (NPB), N,N′-bis(naphthalen-2-yl)-N,N′-bis(phenyl)-benzidine (—NPB), N,N′-bis(naphthalen-1-yl)-N,N′-bis(phenyl)-2,2′-dimethylbenzidine (-NPD), Di-[4-(N,N-ditolyl-amino)-phenyl]cyclohexane (TAPC), N,N,N′,N′-tetra-naphthalen-2-yl-benzidine (-TNB), N4,N4,N4′,N4′-tetra(biphenyl-4-yl)biphenyl-4,4′-diamine (TPD15), poly(9,9-dioctylfluorene-co-bis-N,N(4-butylphenyl)-bis-N,N,4-phenylenediamine) (PFB), poly(9,9(4-butylphenyl)diphenylamine) (TFB), poly(9,9,N(4-butylphenyl)-bis-N,N) (BFB), poly(9,9-dioctylfluorene-co-bis-N,N(4-methoxyphenyl)-bis-N,N,4-phenylenediamine) (PFMO) and the like, but the present invention is not limited thereto.

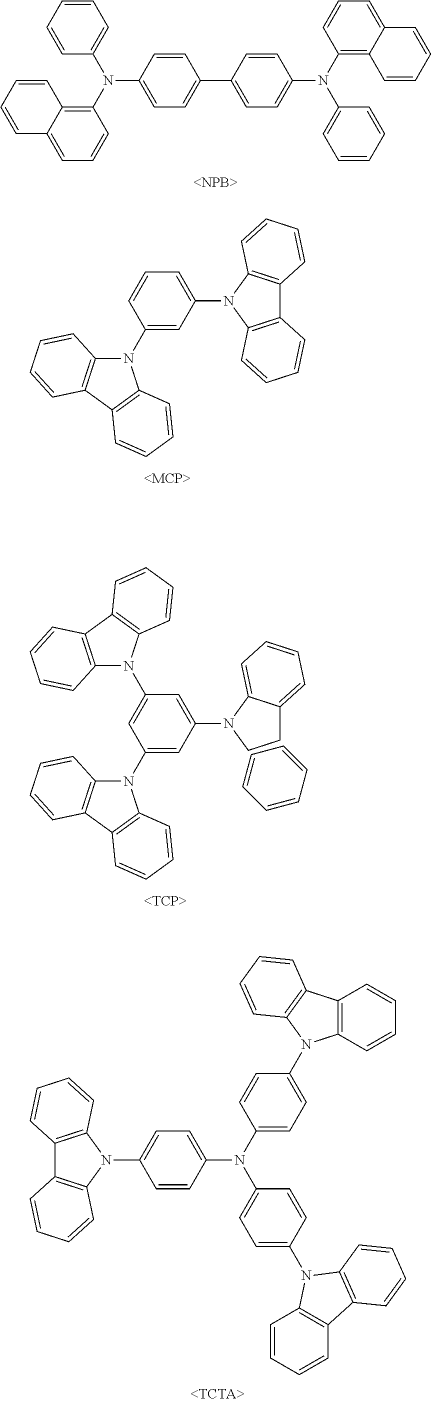

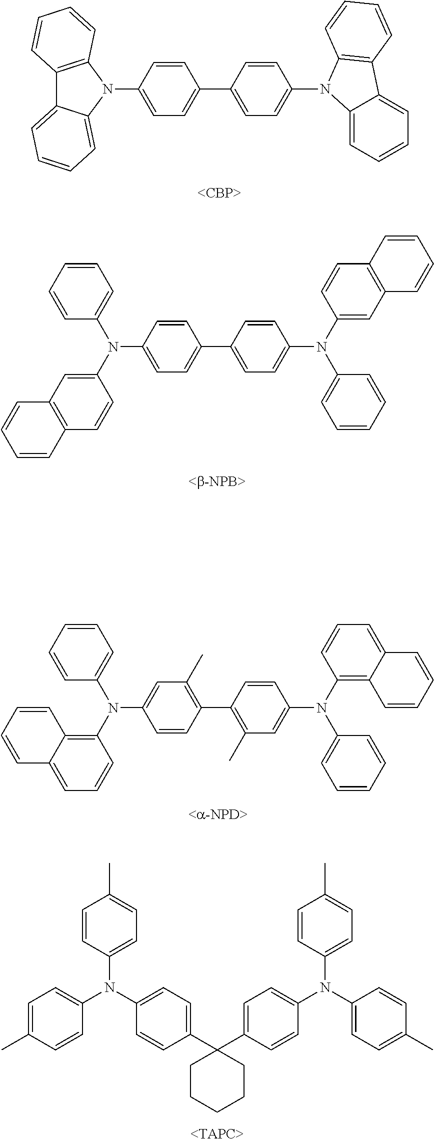

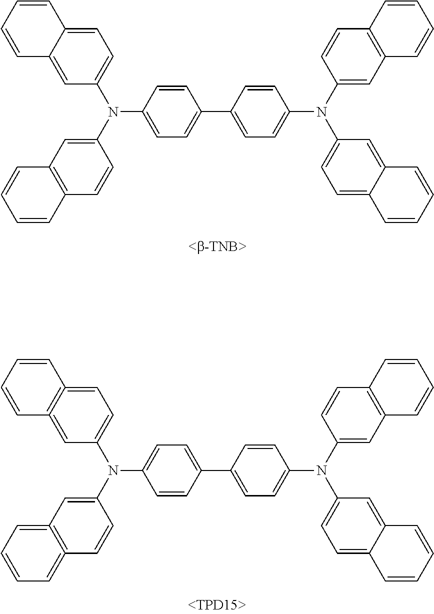

The hole transport layer 140 may have a thickness of 5 nm to 100 nm, for example, 10 nm to 60 nm. When the thickness of the hole transport layer 140 satisfies the above range, it is possible to obtain excellent hole transport characteristics without increasing a driving voltage.

The light-emitting layer 150 may be formed by a method that is arbitrarily selected from among various known methods such as a vacuum deposition method, a spin coating method, a casting method, a Langmuir-Blodgett (LB) method, an ink jet printing method, a nozzle printing method, a slot-die coating method, a doctor blade coating method, a screen printing method, a dip coating method, a gravure printing method, a reverse-offset printing method, a physical transfer method, and a spray coating method. In this case, deposition conditions and coating conditions may be changed according to a target compound, a structure of a target layer, thermal characteristics and the like, but may be selected within a range similar to that of the conditions for forming the hole transport layer 140 as described above.

The light-emitting layer 150 may be made of a single light-emitting material, and may include a host and a dopant.

Examples of the host may include Alq₃, CBP (4,4′-N,N′-dicarbazole-biphenyl), 9,10-di(naphthalene-2-yl)anthracene (ADN), TCTA, TAPC, TPBI (1,3,5-tris(N-phenyl-benzimidazol-2-yl)benzene(1,3,5-tris(N-phenylbenzimidazole-2-yl)benzene)), TBADN(3-tert-butyl-9,10-di(naphth-2-yl) anthracene), E3 (refer to the following chemical formula), BeBq₂ (refer to the following chemical formula) and mixtures thereof, but the present invention is not limited thereto. As necessary, NPB, which is an exemplary material of the hole transport layer 140, may be used as the host.

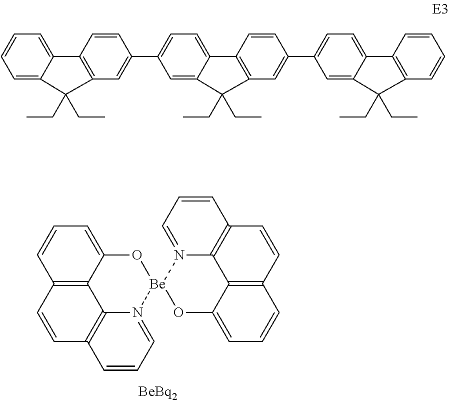

Meanwhile, as a known red dopant, rubrene (5,6,11,12-tetraphenyl naphthacene), PtOEP, Ir(piq)₃, Btp₂Ir(acac) or the like may be used, but the present invention is not limited thereto.

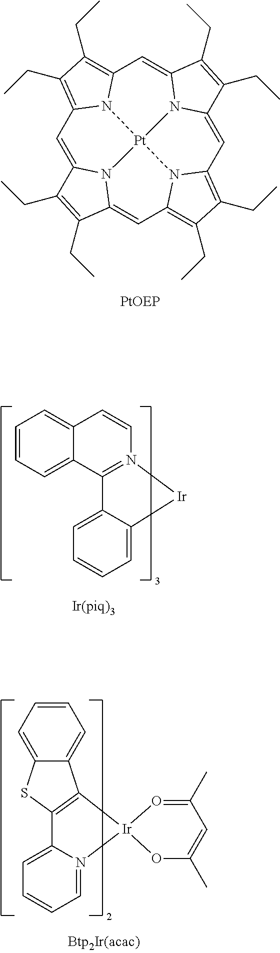

Also, as a known green dopant, Ir(ppy)₃(ppy=phenylpyridine), Ir(ppy)₂(acac), Ir(mpyp)₃, C545T (10-(2-benzothiazolyl)-1,1,7,7-tetramethyl-2,3,6,7-tetrahydro-1H,5H,11H-[1]benzopyrano[6,7,8-ij]quinolizin-11-one, refer to the following chemical formula) or the like may be used, but the present invention is not limited thereto.

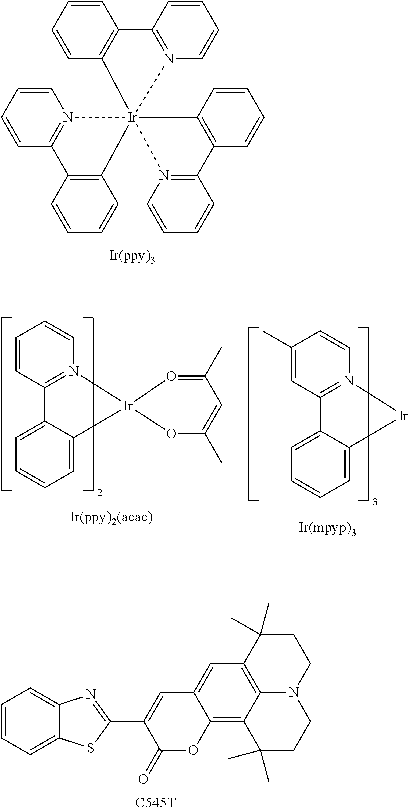

Meanwhile, as a known blue dopant, F₂Irpic, (F₂ppy)₂Ir(tmd), Ir(dfppz)₃, ter-fluorene, 4,4-bis[4-(di-p-tolyl-amino)styryl]biphenyl (DPAVBi), 2,5,8,11-tetra-tert-butylperylene (TBP) or the like may be used, but the present invention is not limited thereto.

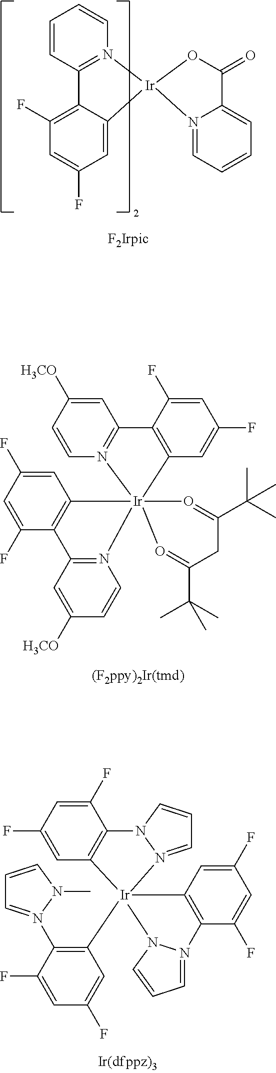

The light-emitting layer 150 may have a thickness of 10 nm to 100 nm, for example, 10 nm to 60 nm. When the thickness of the light-emitting layer 150 satisfies the above range, it is possible to obtain excellent light emitting characteristics without increasing the driving voltage.

A hole blocking layer (not illustrated in FIG. 2) is used to prevent triplet excitons or holes of the light-emitting layer 150 (for example, when the light-emitting layer 150 includes a phosphorescent compound) from spreading to the second electrode 180 or the like, may be additionally formed above the light-emitting layer 150, and may be formed by a method that is arbitrarily selected from among various known methods such as a vacuum deposition method, a spin coating method, a casting method, and an LB method. In this case, deposition conditions and coating conditions may be changed according to a target compound, a structure of a target layer, thermal characteristics and the like, but may be selected within a range similar to that of conditions for forming the hole transport layer 140 as described above.

The hole blocking material may be arbitrarily selected from among known hole blocking materials. For example, oxadiazole derivatives, triazole derivatives, or phenanthroline derivatives may be used.

The hole blocking layer may have a thickness of about 5 nm to 100 nm, for example, 10 nm to 30 nm. When the thickness of the hole blocking layer satisfies the above range, it is possible to obtain excellent hole blocking characteristics without increasing the driving voltage.

The electron transport layer 160 may be formed above the light-emitting layer 150 or the hole blocking layer using a method that is arbitrarily selected from among various known methods such as a vacuum deposition method, a spin coating method, a nozzle printing method, a casting method, a gravure printing method, a slot-die coating method, a screen printing method, and an LB method. In this case, deposition conditions and coating conditions may be changed according to a target compound, a structure of a target layer, thermal characteristics and the like, but may be selected within a range similar to that of conditions for forming the hole transport layer as described above.

A known electron transport material may be used as a material of the electron transport layer 160. For example, the electron transport layer may include quinoline derivatives, and particularly, tris(8-hydroxyquinoline)aluminum (Alq3), bis(2-methyl-8-quinolinolate)-4-(phenylphenolato)aluminium (Balq), bis(10-hydroxybenzo[h]quinolinato)-beryllium (Bebq2), 2,9-dimethyl-4,7-diphenyl-1,10-phenanthroline (BCP), 4,7-diphenyl-1,10-phenanthroline (Bphen), (2,2,2-(benzene-1,3,5-triyl)-tris(1-phenyl-1H-benzimidazole (TPBI), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), 2,9-bis(naphthalen-2-yl)-4,7-diphenyl-1,10-phenanthroline (NBphen), tris(2,4,6-trimethyl-3-(pyridin-3-yl)phenyl)borane (3TPYMB), phenyl-dipyrenylphosphine oxide (POPy2), 3,3′,5,5′-tetra[(m-pyridyl)-phen-3-yl]biphenyl (BP4mPy), 1,3,5-tri[(3-pyridyl)-phen-3-yl]benzene (TmPyPB), 1,3-bis[3,5-di(pyridin-3-yl)phenyl]benzene (BmPyPhB), bis (10-hydroxybenzo[h]quinolinato)beryllium (Bepq2), diphenylbis(4-(pyridin-3-yl)phenyl)silane (DPPS), 1,3,5-tri(p-pyrid-3-yl-phenyl)benzene (TpPyPB), 1,3-bis[2-(2,2′-bipyridine-6-yl)-1,3,4-oxadiazo-5-yl]benzene (Bpy-OXD), or 6,6′-bis[5-(biphenyl-4-yl)-1,3,4-oxadiazo-2-yl]-2,2′-bipyridyl (BP-OXD-Bpy), but the present invention is not limited thereto.

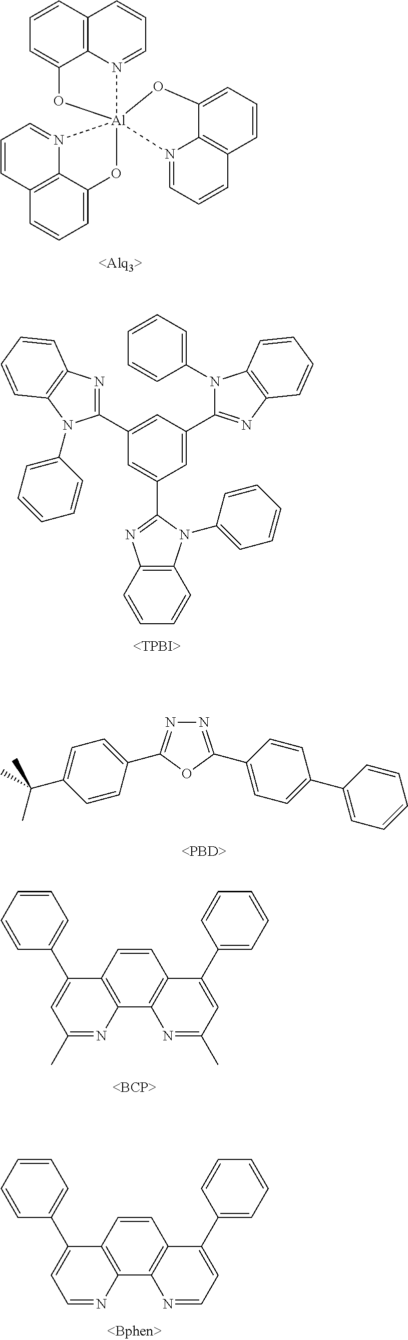

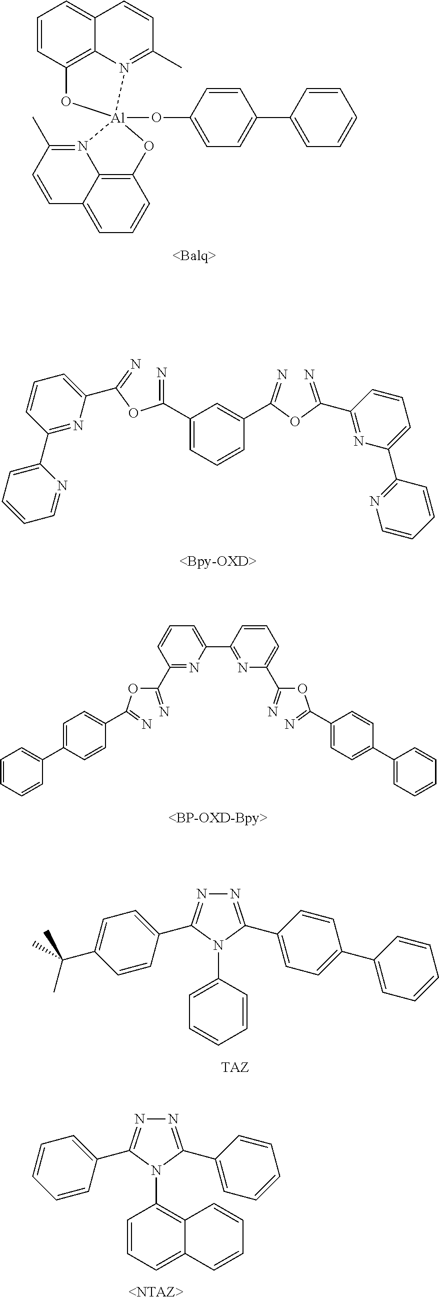

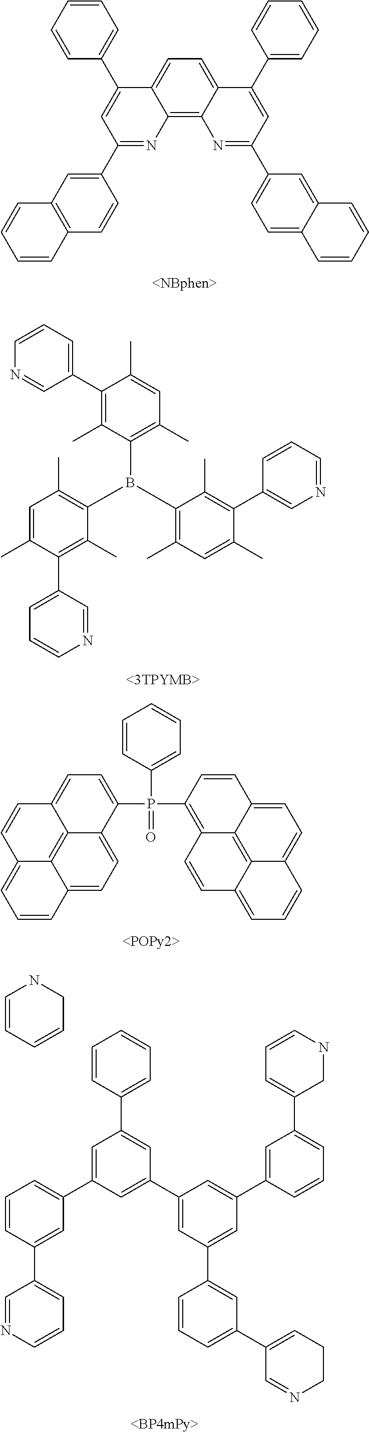

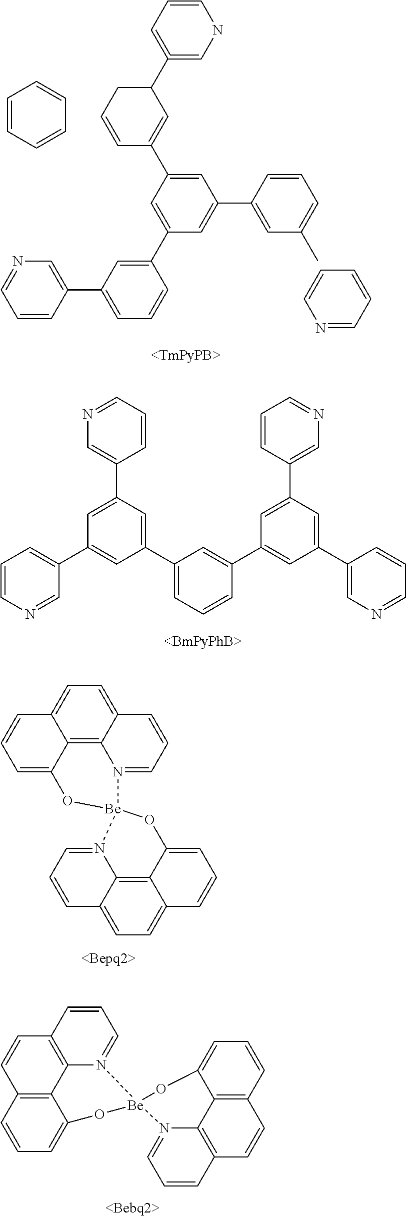

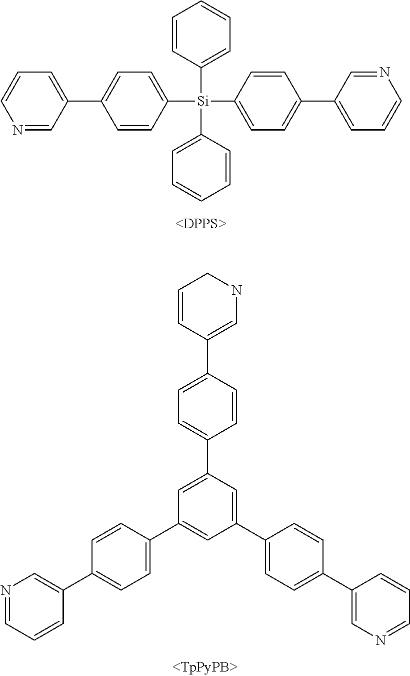 [SMILES: c1ccc([Si](c2ccccc2)(c2ccc(-c3cccnc3)cc2)c2ccc(-c3cccnc3)cc2)cc1 ; C1=CC(c2ccc(-c3cc(-c4ccc(-c5cccnc5)cc4)cc(-c4ccc(-c5cccnc5)cc4)c3)cc2)=CNC1]

The electron transport layer 160 may have a thickness of about 5 nm to 100 nm, for example, 15 nm to 50 nm. When the thickness of the electron transport layer 160 satisfies the above range, it is possible to obtain excellent electron transport characteristics without increasing the driving voltage.

The electron injection layer 170 may be formed above the electron transport layer 160. A known electron injection material, iF, NaCl, NaF, CsF, Li₂O, BaO, BaF₂, Cs₂CO₃, Liq (lithium quinolate) or the like may be used as a material for forming the electron injection layer. Deposition conditions of the electron injection layer 170 may be changed according to a compound to be used, but may be generally selected within almost the same condition ranges as when the hole injection layer is formed.

The electron injection layer 170 may have a thickness of about 0.1 nm to 10 nm, for example, 0.5 nm to 5 nm. When the thickness of the electron injection layer 170 satisfies the above range, it is possible to obtain a satisfactory electron injection characteristic without substantially increasing the driving voltage.

Also, the electron injection layer may be formed as a layer that includes metal derivatives of LiF, NaCl, CsF, NaF, Li₂O, BaO, or Cs₂CO₃ at a content of 1% to 50% with respect to the material of the electron transport layer such as Alq₃, TAZ, Balq, Bebq₂, BCP, TBPI, TmPyPB, or TpPyPB, and is doped with a metal such as Li, Ca, Cs, or Mg and has a thickness of 1 nm to 100 nm.

The second electrode 180 serves as a cathode. A metal, an alloy, an electrically conductive compound or combinations thereof may be used as a material of the second electrode 180. As a specific example, lithium (Li), magnesium (Mg), aluminium (Al), aluminium-lithium (Al—Li), calcium (Ca), magnesium-indium (Mg—In), magnesium-silver (Mg—Ag) or the like may be used. Also, in order to obtain a top light-emitting element, an ITO, an IZO or the like may be used.

The organic light-emitting element 100 includes the hybrid electrode having a high work function and high conductivity 1 described above as the anode. Therefore, very high hole injection efficiency may be obtained without forming the hole injection layer. Further, it is possible to prevent electrons from being introduced into the hybrid electrode having a high work function and high conductivity 1 through the hole transport layer 140. The organic light-emitting element 100 may have excellent electrical characteristics. When a flexible substrate is used as the substrate 110, the organic light-emitting element 100 may have flexible characteristics.

The organic light-emitting element 100 of FIG. 2 has a structure in which the hole transport layer 140 is positioned between the high work function and high conductivity hybrid thin film 1 which serves as the anode and the light-emitting layer 150. However, various modifications may be possible, for example, without forming the hole transport layer 140, the second surface 130B of the work function-tuning layer 130 of the hybrid electrode having a high work function and high conductivity 1 which serves as the anode may be in contact with the light-emitting layer 150.

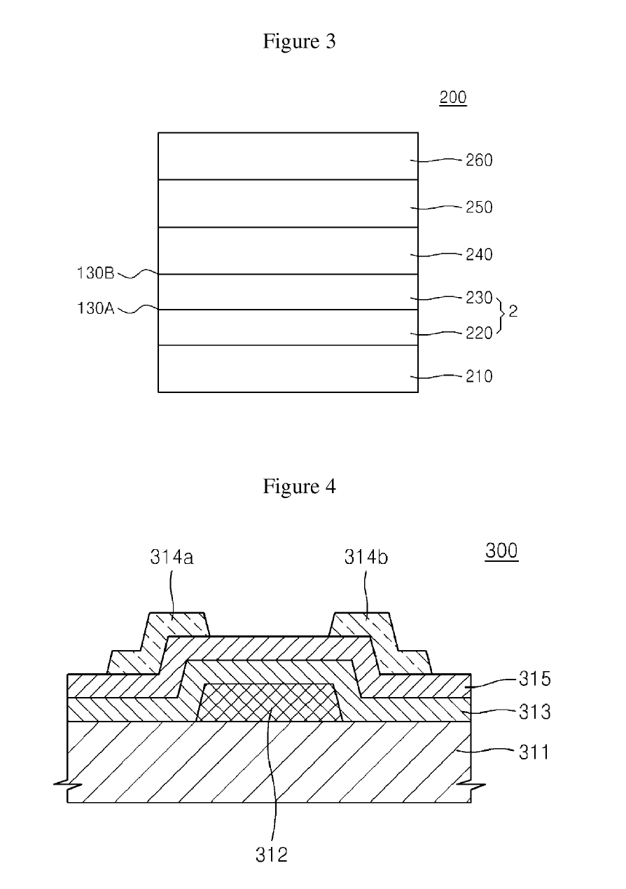

FIG. 3 schematically illustrates an implementation example of an organic solar cell including the electrode having a high work function described above.

An organic solar cell 200 of FIG. 3 includes a substrate 210, a hybrid electrode having a high work function and high conductivity 2, a photoactive layer 240, an electron transport region 250 and a second electrode 260. Light radiated to the organic solar cell 200 may be separated into a hole and an electron in the photoactive layer 240, the electron may move to the second electrode 260 through the electron transport region 250, and the hole may move to the hybrid electrode having a high work function and high conductivity 2.

The hybrid electrode having a high work function and high conductivity 2 includes a conductivity-tuning layer 220 and a work function-tuning layer 230. The work function-tuning layer 230 is positioned between the photoactive layer 240 and the conductivity-tuning layer 220.

For descriptions of the substrate 210 and the hybrid electrode having a high work function and high conductivity 2 of FIG. 3 refer to descriptions of the substrate 110 and the hybrid electrode having a high work function and high conductivity 1 of FIG. 1.

The photoactive layer 240 may include a material that can separate holes and electrons from radiated light. For example, the photoactive layer 240 may include an electron donor and a hole receptor. The photoactive layer 240 may have various structures such as a single layer including the electron donor and the hole receptor, or multiple layers including a layer containing the electron donor and a layer containing the hole receptor.

The electron donor may include a p-type conductive polymer material containing a − electron. Examples of the electron donor may include P3HT (poly(3-hexylthiophene), a polysiloxane carbazole, a polyaniline, a polyethylene oxide, (poly(l-methoxy-4-(0-disperse red 1)-2,5-phenylene-vinylene), MEH-PPV (poly-[2-methoxy-5-(2ethoxyhexyloxy)-1,4-phenylenevinylene]:poly-[2-methoxy-5-(2′-ethylhexyloxy)-1,4-phenylene vinylene]), MDMO-PPV (poly[2-methoxy-5-3 (3,7dimethyloctyloxy)-1,4-phenylenevinylene], poly[2-methoxy-5-3(3′,7′-dimethyloctyloxy)-1-4-phenylenevinylene]), PFDTBT (poly(2,7-(9,9-dioctyl)-fluorene-alt-5,5-(4,7-di-2-thienyl-2,1,3-benzothiadiazole), poly((2,7-(9,9-dioctyl)-fluorene)-alt-5,5-(4′,7′-di-2-thienyl-2′,1′,3′-benzothiadiazole)), PCPDTBT (poly[N heptadecanoyl-2,7-carbazole-alt-5,5-(4,7-di-2-thienyl-2,1,3 benzothiazole), a polyindole, a polycarbazole, a polypyridiazine, a polyisothianaphthene, a polyphenylene sulfide, a polyvinylpyridine, a polythiophene, a polyfluorene, a polypyridine, CuPc (Copper Phthalocyanine), SubPc (subphthalocyanine), ClAlPc (Chloro-aluminum phthalocyanine), TAPC, and derivatives thereof, but the present invention is not limited thereto. Combinations (including a blend, a copolymer or the like) of two or more of specific examples of the electron donor may also be used.

As the hole receptor, a fullerene (for example, C60, C70, C74, C76, C78, C82, C84, C720, or C860) having high electron affinity; fullerene derivatives (for example, PCBM ([6,6]-phenyl-C61 butyric acid methyl ester), C71-PCBM, C84-PCBM, bis-PCBM or the like); perylene; an inorganic semiconductor including a nanocrystal such as CdS, CdTe, CdSe, or ZnO; a carbon nanotube, a carbon nanorod polybenzimidazole (PBI), TCBI (3,4,9,10 perylenetetracarboxylic bisbenzimidazole) or mixtures thereof may be used, but the present invention is not limited thereto.

For example, the photoactive layer 240 may be a single layer that includes P3HT as the electron donor and the fullerene derivative PCBM as the hole receptor, but the present invention is not limited thereto.

When light is radiated to the photoactive layer 240, an exciton, which is a pair of an electron and a hole, is formed due to photoexcitation. This exciton is separated into an electron and a hole due to a difference between electron affinities of the electron donor and the hole receptor at an interface between the electron donor and the hole receptor.

The electron transport region 250 may include the electron transport layer and the electron extraction layer. The electron transport layer helps the electron generated in the photoactive layer 240 to be transported to the second electrode 260.

As to the electron transport layer material, refer to the material of the electron transport layer 160 of FIG. 1.

The electron extraction layer may aid the electron generated in the photoactive layer 240 to be transported to the second electrode 260. LiF, NaCl, CsF, NaF, Li₂O, BaO, or Cs₂CO₃ may be used, for example, as a material of the electron extraction layer but the present invention is not limited thereto. The electron injection layer may have a thickness of about 1 nm to about 100 nm, and about 3 nm to about 90 nm. When the thickness of the electron injection layer satisfies the above range, it is possible to obtain a satisfactory electron injection characteristic without substantially increasing the driving voltage.

Also, the electron extraction layer may be formed as a layer that includes metal derivatives of LiF, NaCl, CsF, NaF, Li₂O, BaO, or Cs₂CO₃ at a content of 1% to 50% with respect to the material of the electron transport layer such as Alq₃, TAZ, Balq, Bebq₂, BCP, TBPI, TmPyPB, or TpPyPB, and is doped with a metal such as Li, Ca, Cs, or Mg and has a thickness of 1 nm to 100 nm.

The photoactive layer 240 and the electron transport region 250 of the organic solar cell may be manufactured by vacuum deposition and a solution process. The vacuum deposition may generally use a thermal deposition method. The solution process may use a spin-coating method, an ink jet printing method, a nozzle printing method, a spray coating method, a slot-die coating method, a screen printing method, a doctor blade coating method, a gravure printing method or an offset printing method.

The second electrode 260 may use a metal, an alloy, an electrically conductive compound having a relatively low work function and combinations thereof. As a specific example, lithium (Li), magnesium (Mg), aluminium (Al), aluminium-lithium (Al—Li), calcium (Ca), magnesium-indium (Mg—In), magnesium-silver (Mg—Ag) or the like may be used.

Since the organic solar cell 200 uses the hybrid electrode having a high work function and high conductivity 2 described above, the hole generated in the photoactive layer 240 may easily move to the hybrid electrode having a high work function and high conductivity 2. Therefore, it is possible to provide excellent electrical characteristics.

The organic solar cell 200 of FIG. 3 includes no hole extraction layer, but various modifications may be possible, for example, a hole extraction layer is further positioned between the hybrid electrode having a high work function and high conductivity 2 and the photoactive layer 240 in the organic solar cell 200 of FIG. 2. The material of the hole transport layer 140 of FIG. 1 may be used as a material of the hole extraction layer.

FIG. 4 schematically illustrates an implementation example of an organic thin film transistor including a hybrid electrode that has a high work function and high conductivity and a laminated structure.

An organic thin film transistor 300 of FIG. 4 includes a substrate 311, a gate electrode 312, an insulating layer 313, an organic semiconductor layer 315 and source and drain electrodes 314a and 314b. At least one of the gate electrode 312 and the source and drain electrodes 314a and 314b may be the hybrid electrode having a high work function and high conductivity described above.

For descriptions of the substrate 311 refer to descriptions of the substrate 110. The gate electrode 312 having a predetermined pattern is formed on the substrate 311. The gate electrode 312 may be the hybrid electrode having a high work function and high conductivity described above. Alternatively, for example, a metal such as Au, Ag, Cu, Ni, Pt, Pd, Al, or Mo, or an alloy of metals such as Al:Nd, or Mo:W may be used, but the present invention is not limited thereto.

The insulating layer 313 is provided above the gate electrode 312 to cover the gate electrode 312. The insulating layer 313 may be made of various materials, for example, an inorganic material such as a metal oxide or a metal nitride, or an organic material such as a flexible organic polymer.

The organic semiconductor layer 315 is formed above the insulating layer 313. The organic semiconductor layer 315 may include pentacene, tetracene, anthracene, naphthalene, alpha-6-thiophene, alpha-4-thiophene, perylene and derivatives thereof, rubrene and derivatives thereof, coronene and derivatives thereof, perylene tetracarboxylic diimide and derivatives thereof, perylene tetracarboxylic dianhydride and derivatives thereof, a polythiophene and derivatives thereof, a polyparaphenylene vinylene and derivatives thereof, a polyparaphenylene and derivatives thereof, a polyfluorene and derivatives thereof, a polythiophenevinylene and derivatives thereof, a polythiophene-heterocyclic aromatic copolymer and derivatives thereof, oligoacene of naphthalene and derivatives thereof, oligo thiophene of alpha-5-thiophene and derivatives thereof, phthalocyanine with or without a metal and derivatives thereof, pyromelliticdianhydride and derivatives thereof, and pyromellitic diimide and derivatives thereof, but the present invention is not limited thereto.

The source and drain electrodes 314a and 314b are formed on the organic semiconductor layer 315. As illustrated in FIG. 4, the source and drain electrodes 314a and 314b are provided to partially overlap the gate electrode 312, but the present invention is not necessarily limited thereto. The source and drain electrodes 314a and 314b may be the hybrid electrode having a high work function and high conductivity described above. Alternatively, the source and drain electrodes 314a and 314b may use a noble metal of 5.0 eV or more, for example, Au, Pd, Pt, Ni, Rh, Ru, Ir, Os or combinations of two or more thereof in consideration of a work function of the material of the organic semiconductor layer.

Meanwhile, according to another implementation example, in the work function-tuning layers 130 and 230 of the hybrid electrodes having a high work function and high conductivity 1 and 2, in addition to the material having low surface energy described above, at least one additive selected from among a carbon nanotube, a graphene, a reduced graphene oxide, a metallic nanowire, a metallic carbon nanodot, a semiconductor quantum dot, a semiconductor nanowire and a metallic nanodot may be further included. It is possible to further improve conductivity of the hybrid electrodes having a high work function and high conductivity 1 and 2 due to the additive.

As an example of the electronic element, the organic light-emitting element, the organic solar cell and the organic thin film transistor have been described with reference to FIGS. 1 to 4. However, the example of the electronic element is not limited thereto.

For example, the hybrid electrode having a high work function and high conductivity is used as the second electrode 180 of the organic light-emitting element of FIG. 1 or the second electrode 260 of the organic solar cell of FIG. 3, and may serve as the cathode. In this case, the work function-tuning layer may be disposed to face the light-emitting layer of the organic light-emitting element or the photoactive layer of the organic solar cell, or in a direction opposite thereto. The hybrid electrode having a high work function and high conductivity may be formed first on a base film, and then transferred onto the electron injection layer 170 of the organic light-emitting element or onto the electron transport region 250 of the organic solar cell using, for example, Laser Induced Thermal Imaging (LITI) or a Transfer Printing process.

Also, the hybrid electrode having a high work function and high conductivity may be used to manufacture an inverted organic light-emitting element or the organic solar cell.

The electronic element is not limited to the organic light-emitting element, the organic solar cell and the organic thin film transistor, but may include an organic memory element, an organic photodetector or an organic CMOS sensor.

The present invention has been described with reference to the examples illustrated in the drawings, but these are only examples. It will be understood by those skilled in the art that various modifications and equivalent other examples may be made. Therefore, the scope of the present invention is defined by the appended claims.

### Example 1

### Manufacture of Hybrid Electrode Having a High Work Function and High Conductivity

### <Formation of Conductivity-Tuning Layer>

As a conductivity-tuning layer, a mixture including a PEDOT:PSS (PH500 of Heraeus CLEVIOS™) solution and DMSO of 5 wt % was prepared. A PET substrate was spin-coated with the mixture, heated for 10 minutes at 200° C., and a thin film having a thickness of 100 nm was formed. Conductivity of the conductive polymer layer 1 was 300 S/cm (measured by a 4-point probe).

### <Formation of Work Function Control Layer>

As a work function-tuning layer, a mixture in which a solution (a polymer 100 is dispersed at 5 wt % in a mixture of water and an alcohol (water:alcohol=4.5:5.5 (v/v)), commercially available from Aldrich Co.) of the polymer 100 was diluted to 5 wt % with isopropyl alcohol (commercially available from J.T. Baker, purity is CMOS grade) was prepared.

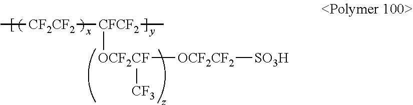

(in the polymer 100, x=1300, y=200, and z=1)

The conductive polymer layer 1 was spin-coated with the mixture at 5000 rpm for 90 seconds, heated for 10 minutes at 150° C., and an electrode 1 was formed.

### Comparative Example A

An electrode A was manufactured using the same method as the method of manufacturing the conductive polymer layer 1 except that coating of the work function-tuning layer as in the electrode 1 was not performed, and a mixture including the PEDOT:PSS (PH500, commercially available from Heraeus CLEVIOS™) solution and DMSO of 5 wt % was used to form a thin film.

### Comparative Example B

Similar to the electrode 1, as a conductivity-tuning layer, a mixture including the PEDOT:PSS (PH500, commercially available from Heraeus CLEVIOS™) solution and DMSO of 5 wt % was used to form a thin film. However, unlike the electrode 1, as a work function-tuning layer, a mixture including the PEDOT:PSS (PH500, commercially available from Heraeus CLEVIOS™), a solution of the polymer 100 and dimethylsulfoxide (DMSO) of 5 wt % was prepared. Here, a mixing ratio of the PEDTO:PSS solution (PH500, commercially available from Heraeus CLEVIOS™) and the solution of the polymer 100 was adjusted such that a content (based on a solid) of the polymer 100 was 1.0 part by weight with respect to 1 part by weight of PEDOT. The conductivity-tuning layer was spin-coated with the mixture at 2000 rpm for 90 seconds, heated for 10 minutes at 150° C., and an electrode B was formed.

### Comparative Example C

A mixing ratio of the PEDTO:PSS solution (PH500, commercially available from Heraeus CLEVIOS™) and the solution of the polymer 100 was adjusted such that a content (based on a solid) of the polymer 100 was 1.0 part by weight with respect to 1 part by weight of PEDOT. The mixture was spin-coated at 2000 rpm for 90 seconds, heated for 10 minutes at 150° C., and an electrode C was formed.

### Evaluation Example 1

### Evaluation of Hybrid Electrode Having a High Work Function and High Conductivity

### <Evaluation of Work Function and Conductivity of Hybrid Electrode Having a High Work Function and High Conductivity>

In the electrode 1 and the electrode A, a work function was evaluated using an ultraviolet photoelectron spectroscopy in air (model name AC2, commercially available from Niken Keiki), and conductivity was evaluated using a 4-point probe. The results are shown in Table 1.

TABLE 1

| | Work function (eV) | Conductivity (S/cm) |
|---|---|---|
| Electrode 1 | 5.80 | 150 |
| Electrode A | 4.73 | 300 |
| Electrode B | 5.02 | 150 |
| Electrode C | 5.07 | 125 |

It can be seen that the polymer 100 provides a high work function, but conductivity decreases since the polymer 100 is an insulator. Also, it can be seen that the electrode B in which a mixture of the conductive polymer and the polymer 100 was used as the work function-tuning layer has a lower work function than the electrode 1. Additionally, it can be seen that the electrode C that was formed by simply mixing the polymer 100, which is the material having low surface energy, and the conductive polymer has a lower work function and conductivity than the electrode 1.

### Example 2

### Manufacture of OPV

According to Example 1, the electrode 1 was formed on an organic substrate as an anode, a PCDTBT:PC70BM photoactive layer having a thickness of 80 nm was formed on the electrode 1 using a spin coating method, a Ca electron extraction layer having a thickness of 1 nm and an Al cathode having a thickness of 100 nm were sequentially formed (in the above, a vacuum deposition method was used), and an OPV 1 was manufactured.

### Comparative Example 1

An OPV A was manufactured using the same method as in Example 2 except that the electrode A of Comparative Example A was used instead of the electrode 1.

### Comparative Example 2

An ITO electrode (15 Ω/cm² (1200 Å) ITO glass substrate, commercially available from Corning) was spin-coated with a PEDOT:PSS aqueous solution (PSS was 6 parts by weight with respect to 1 part by weight of CLEVIOS™ PVPAI4083/PEDOT), baked at 200° C. for 10 minutes, and a PEDOT:PSS hole extraction layer having a thickness of 30 nm was formed. A PCDTBT:PC70BM photoactive layer having a thickness of 80 nm, a Ca electron extraction layer having a thickness of 1 nm and an Al cathode having a thickness of 100 nm were sequentially formed on the hole injection layer (in the above, a vacuum deposition method was used), and an OPV2 was manufactured.

### Comparative Example 3

An OPV B was manufactured using the same method as in Example 2 except that the electrode B of Comparative Example B was used instead of the electrode 1.

### Comparative Example 4

An OPV C was manufactured using the same method as in Example 2 except that the electrode C of Comparative Example C was used instead of the electrode 1.

Evaluation Example 2: evaluation of OPV

In the OPVs 1 and 2 and the OPVs A to C, efficiency (PCE), a short-circuit current (J_{SC}), an open circuit voltage (V_{OC}), and a Fillfactor (FF) and the like were evaluated using a Keithley2400 source measurement device, a Newport 69907 power supply and a Digital exposure controller operation. The results are shown in Table 2. It can be seen that the OPV 1 has a more excellent short-circuit current (J_{SC}), open circuit voltage (V_{OC}) and efficiency (PCE) than the OPV 2 and the OPVs A to C from Table 2.

TABLE 2

| | OPV A | OPV B | OPV C | OPV 2 | OPV 1 |
|---|---|---|---|---|---|
| Fitted V_{OC} (V) | 0.838 | 0.862 | 0.870 | 0.856 | 0.878 |
| Fitted J_{SC} (mA/cm²) | 10.4 | 10.9 | 11.0 | 10.9 | 11.2 |
| FF (%) | 47.0 | 55.2 | 45.2 | 57.4 | 56.5 |
| PCE (%) | 4.1 | 5.2 | 4.3 | 5.5 | 5.6 |

### Example 3

### Manufacture of OLED

The electrode 1 was formed on a glass substrate as the anode according to the method described in Example 1, a TAPC hole transport layer, a TCTA:Ir(ppy)₃ (Ir(ppy)₃ was 3 wt %) having a thickness of 5 nm, a CBP:Ir(ppy)₃ (Ir(ppy)₃ was 4 wt %) light-emitting layer having a thickness of 5 nm, a TPBI electron transport layer having a thickness of 65 nm, a LiF electron injection layer having a thickness of 1 nm and an Al cathode having a thickness of 110 nm were sequentially formed thereon (in the above, a vacuum deposition method was used), and an OLED 1 was manufactured.

### Comparative Example 5

An OLED A was manufactured using the same method as in Example 3 except that the electrode A of Comparative Example A was used as the anode instead of the electrode 1.

### Comparative Example 6

An ITO electrode (15 Ω/cm² (1200 Å) ITO glass substrate, commercially available from Corning) was spin-coated with a PEDOT:PSS aqueous solution (PSS was 6 parts by weight with respect to 1 part by weight of CLEVIOS™ PVP AI4083/PEDOT), baked at 150° C. for 30 minutes, and a PEDOT:PSS hole injection layer having a thickness of 50 nm was formed. A TAPC hole transport layer having a thickness of 15 nm, TCTA:Ir(ppy)₃ (Ir(ppy)₃ was 3 wt %) having a thickness of 5 nm, a CBP:Ir(ppy)₃ (Ir(ppy)₃ was 4 wt %) light-emitting layer having a thickness of 5 nm, a TPBI electron transport layer having a thickness of 65 nm, a LiF electron injection layer having a thickness of 1 nm and an Al cathode having a thickness of 110 nm were sequentially formed (in the above, a vacuum deposition method was used) on the hole injection layer, and an OLED 2 was manufactured.

### Comparative Example 7

An OLED B was manufactured using the same method as in Example 3 except that the electrode B of Comparative Example B was used as the anode instead of the electrode 1.

### Comparative Example 8

An OLED C was manufactured using the same method as in Example 3 except that the electrode C of Comparative Example C was used as the anode instead of the electrode 1.

### Evaluation Example 3

### Evaluation of OLED

In the OLEDs 1 and 2 and A to C, efficiency was evaluated using a Keithley 236 source measurement device and a Minolta CS 2000 spectroradiometer. The results are shown in Table 3. Light-emitting efficiency observed in Example 3 was high at 83.1 lm/W. Light-emitting efficiency observed in Comparative Example 5 was 25.2 lm/W. Light-emitting efficiency observed in Comparative Example 6 was 68.0 lm/W. Light-emitting efficiency observed in Comparative Example 7 was 69.2 lm/W. Light-emitting efficiency observed in Comparative Example 8 was 68.2 lm/W. Therefore, it can be seen that the organic light-emitting element of Example 3 has more excellent light-emitting efficiency than others.

TABLE 3

| | OLED A | OLED B | OLED C | OLED 2 | OLED 1 |
|---|---|---|---|---|---|
| Power light-emitting | 25.2 | 69.2 | 68.2 | 68.0 | 83.1 |
| efficiency (lm/W) | | | | | |

### REFERENCE NUMERALS

110, 210: substrate
1, 2: hybrid electrode having a high work function and high conductivity
120, 220: conductivity-tuning layer
130, 230: work function-tuning layer
130A, 230A: first surfaces of work function-tuning layers 130 and 230
130B, 230B: second surfaces of work function-tuning layers 130 and 230

1. An electronic element including a hybrid electrode having a high work function and conductivity and having a conductivity of 1 S/cm or more, the electronic element comprising:
a work function-tuning layer that includes a material having low surface energy, does not include a conductive material, and has a first surface and a second surface that faces the first surface and has a work function of 5.0 eV or more; and
a conductivity-tuning layer that includes at least one of a conductive polymer, a metallic carbon nanotube, a graphene, a reduced graphene oxide, a metallic nanowire, a semiconductor nanowire, a carbon nanodot, a metallic nanodot and a conductive oxide, does not include the material having low surface energy, and is in contact with the first surface of the work function-tuning layer.

2. The electronic element according to claim 1,
wherein the material having low surface energy is a fluorinated material including at least one fluorine atom.

3. The electronic element according to claim 1,
wherein the material having low surface energy is an ionomer that includes one or more repeating units of the following Chemical Formulae 2 to 13: 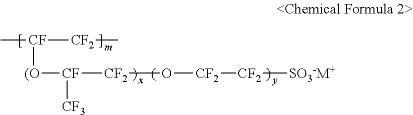
In Chemical Formula 2, m is a number of 1 to 10,000,000, x and y each independently represent a number of 0 to 10, and M⁺ represents Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅OH⁺, CH₃HO⁺, or RCHO⁺ (R is CH₃(CH₂)ₙ—; n is an integer of 0 to 50). 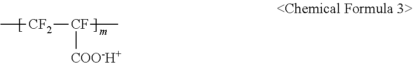
In Chemical Formula 3, m is a number of 1 to 10,000,000. 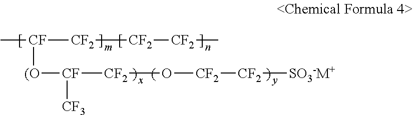
In Chemical Formula 4, m and n satisfy 0<m≦10,000,000, and 0≦n<10,000,000, x and y each independently represent a number of 0 to 20, and M⁺ represents Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; n is an integer of 0 to 50). 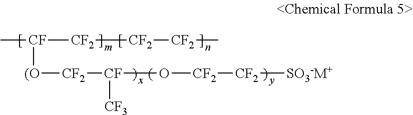
In Chemical Formula 5, m and n satisfy 0<m≦10,000,000, and 0≦n<10,000,000, x and y each independently represent a number of 0 to 20, and M⁺ represents Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅OH⁺, CH₃OH⁺, RCHO⁺ (R is CH₃(CH₂)ₙ—; n is an integer of 0 to 50). 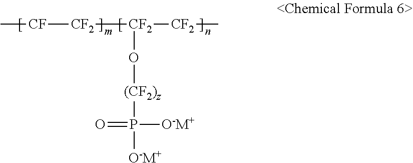
In Chemical Formula 6, m and n satisfy 0<m≦10,000,000, and 0≦n<10,000,000, z is a number of 0 to 20, and M⁺ represents Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; n is an integer of 0 to 50); 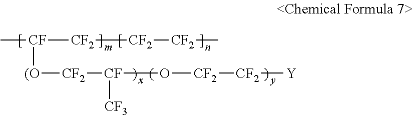
In Chemical Formula 7, m and n satisfy 0<m≦10,000,000, and 0≦n<10,000,000, x and y each independently represent a number of 0 to 20, Y is one selected from among —COO⁻M⁺, —SO₃⁻NHSO₂CF3⁺, and —PO₃²⁻(M⁺)₂, and M⁺ represents Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; n is an integer of 0 to 50). 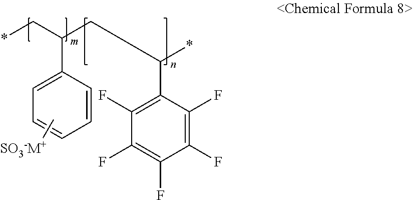
In Chemical Formula 8, m and n satisfy 0<m≦10,000,000 and 0≦n<10,000,000, and M⁺ represents Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅OH⁺, CH₃HO⁺, or RCHO⁺ (R is CH₃(CH₂)ₙ—; n is an integer of 0 to 50). 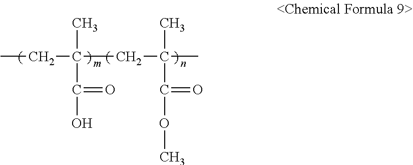
In Chemical Formula 9, m and n satisfy 0<m≦10,000,000, and 0≦n<10,000,000; 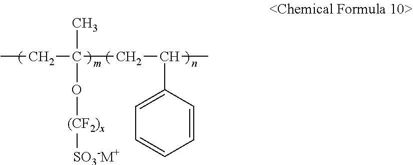
In Chemical Formula 10, m and n satisfy 0<m≦10,000,000, and 0≦n<10,000,000, x is a number of 0 to 20, and M⁺ represents Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; n is an integer of 0 to 50). 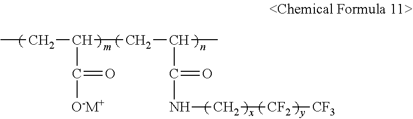
In Chemical Formula 11, m and n satisfy 0<m≦10,000,000, and 0≦n<10,000,000, x and y each independently represent a number of 0 to 20, and M⁺ represents Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; n is an integer of 0 to 50). 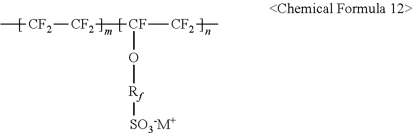
In Chemical Formula 12, m and n satisfy 0<m≦10,000,000, and 0≦n<10,000,000, R_{f}=—(CF₂)_{z}— (z is an integer of 1 to 50, except 2), —(CF₂CF₂O)_{z}CF₂CF₂— (z is an integer of 1 to 50), —(CF₂CF₂CF₂O)_{z}CF₂CF₂— (z is an integer of 1 to 50), and M⁺ represents Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅HO⁺, CH₃HO⁺, or RCHO⁺ (R is CH₃(CH₂)ₙ—; n is an integer of 0 to 50); 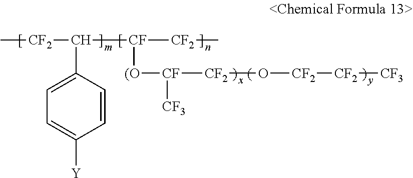
In Chemical Formula 13, m and n satisfy 0≦m<10,000,000, and 0<n≦10,000,000, x and y each independently represent a number of 0 to 20, Y each independently represent one selected from among —SO₃⁻M⁺, —COO⁻M⁺, —SO₃⁻NHSO₂CF3⁺, and —PO₃²⁻(M⁺)₂, and M⁺ represents Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅HO⁺, CH₃OH⁺, or RCHO⁺ (R is CH₃(CH₂)ₙ—; n is an integer of 0 to 50).

4. The electronic element according to claim 1,
wherein the material having low surface energy is a fluorinated ionomer that has any structure of the following Chemical Formulae 14 to 19 or a fluorinated small molecules of the following Chemical Formula 20: 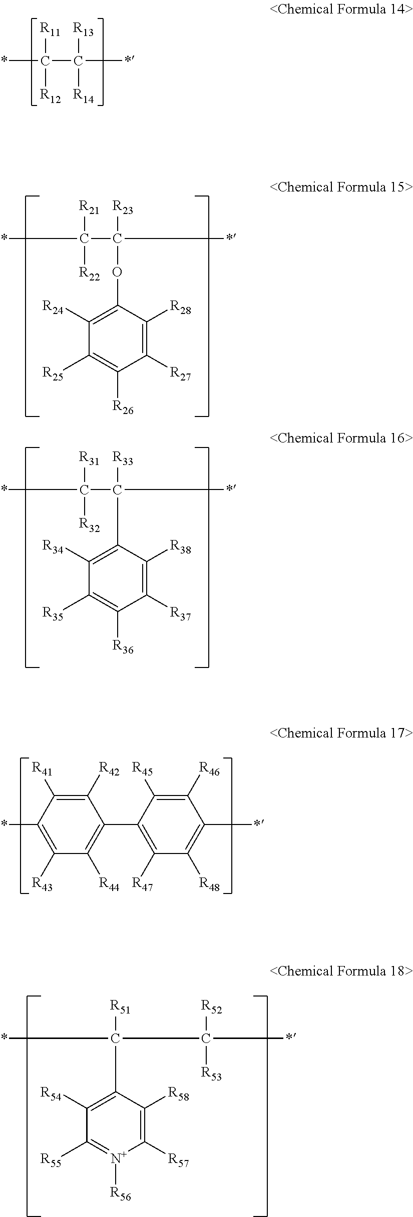 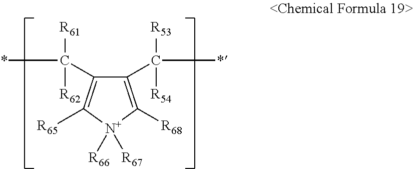
In Chemical Formulae 14 to 19,
R₁₁ to R₁₄, R₂₁ to R₂₈, R₃₁ to R₃₈, R₄₁ to R₄₈, R₅₁ to R₅₈ and R₆₁ to R₆₈ each are independently selected from among hydrogen, —F, a C₁-C₂₀ alkyl group, a C₁-C₂₀ alkoxy group, a C₁-C₂₀ alkyl group substituted with at least one —F, a C₁-C₂₀ alkoxy group substituted with at least one —F, Q₁, —O—(CF₂CF(CF₃)—O)ₙ—(CF₂)ₘ-Q₂ (here, n and m each independently represent an integer of 0 to 20, and n+m is 1 or more) and —(OCF₂CF₂)ₓ-Q₃ (here, x is an integer of 1 to 20), Q₁ to Q₃ represent an ionic group, the ionic group includes an anionic group and a cationic group, the anionic group is selected from among PO₃²⁻, SO₃⁻, COO⁻, I⁻, CH₃COO⁻ and BO₂²⁻, the cationic group includes at least one type of a metal ion and an organic ion, the metal ion is selected from among Na⁺, K⁺, Li⁺, Mg⁺², Zn⁺² and Al⁺³, and the organic ion is selected from among H⁺, CH₃(CH₂)ₙ₁NH₃⁺ (here, n1 is an integer of 0 to 50), NH₄⁺, NH₂⁺, NHSO₂CF₃⁺, CHO⁺, C₂H₅OH⁺, CH₃OH⁺ and RCHO⁺ (here, R is CH₃(CH₂)ₙ₂—, and n2 is an integer of 0 to 50),
at least one of R₁₁ to R₁₄, at least one of R₂₁ to R₂₈, at least one of R₃₁ to R₃₈, at least one of R₄₁ to R₄₈, at least one of R₅₁ to R₅₈ and at least one of R₆₁ to R₆₈ are selected from among —F, a C₁-C₂₀ alkyl group substituted with at least one —F, a C₁-C₂₀ alkoxy group substituted with at least one —F, —O—(CF₂CF(CF₃)—O)ₙ—(CF₂)ₘ-Q₂ and —(OCF₂CF₂)ₓ-Q₃;
X-M^{f}ₙ-M^{h}ₘ-M^{a}ᵣ-Gₚ <Chemical Formula 20>
In Chemical Formula 20,
X represents an end group;
M^{f} represents a unit derived from a fluorinated monomer obtained from a condensation reaction of a perfluoropolyether alcohol, a polyisocyanate and an isocyanate-reactive non-fluorinated monomer;
M^{h} represents a unit derived from a non-fluorinated monomer;
M^{a} represents a unit including a silyl group represented as Si(Y₄)(Y₅)(Y₆);
Y₄, Y₅ and Y₆ each independently represent a substituted or unsubstituted C₁-C₂₀ alkyl group, a substituted or unsubstituted C₆-C₃₀ aryl group or a hydrolyzable substituent, and at least one of Y₄, Y₅ and Y₆ represents the hydrolyzable substituent;
G represents a monohydric organic group including a residue of a chain transfer agent;
n is a number of 1 to 100;
m is a number of 0 to 100;
r is a number of 0 to 100;
n+m+r is at least 2.

5. The electronic element according to claim 1,
wherein the conductive polymer includes a polythiophene, a polyaniline, a polypyrrole, a polystyrene, a sulfonated polystyrene, a poly(3,4-ethylenedioxythiophene), a self-doped conductive polymer, derivatives thereof or combinations thereof.

6. The electronic element according to claim 1,
wherein at least one moiety (here, Z₁₀₀, Z₁₀₁, Z₁₀₂, and Z₁₀₃ each independently represent a hydrogen atom, a halogen atom, a substituted or unsubstituted C₁-C₂₀ alkyl group or a substituted or unsubstituted C₁-C₂₀ alkoxy group) represented as —S(Z₁₀₀) and —Si(Z₁₀₁)(Z₁₀₂)(Z₁₀₃) is combined with surfaces of the metallic nanowire, the semiconductor nanowire, the carbon nanodot and the metallic nanodot.

7. The electronic element according to claim 1,
wherein the conductive oxide is one of an indium tin oxide (ITO), an indium zinc oxide (IZO), SnO₂ and InO₂.

8. The electronic element according to claim 1,
wherein, in the hybrid electrode, a work function observed in the second surface of the work function-tuning layer is selected within a range of 5.0 eV to 6.5 eV.

9. The electronic element according to claim 1,
wherein the work function-tuning layer further includes at least one additive selected from among the carbon nanotube, the graphene, the reduced graphene oxide, the metallic nanowire, a metallic carbon nanodot, a semiconductor quantum dot, the semiconductor nanowire and the metallic nanodot.

10. The electronic element according to claim 1,
wherein the electronic element is an organic light-emitting element, an organic solar cell, an organic transistor, an organic memory element, an organic photodetector or an organic CMOS sensor.

11. The electronic element according to claim 1,
wherein the electronic element is an organic light-emitting element,
wherein the organic light-emitting element includes a substrate, a first electrode, a second electrode and a light-emitting layer positioned between the first electrode and the second electrode,
wherein the first electrode is a hybrid electrode having a high work function and high conductivity, and
wherein a work function-tuning layer is positioned between the light-emitting layer and the conductivity-tuning layer in the hybrid electrode having a high work function and high conductivity.

12. The electronic element according to claim 1,
wherein the electronic element is an organic solar cell,
wherein the organic solar cell includes a substrate, a first electrode, a second electrode, and a photoactive layer positioned between the first electrode and the second electrode,
wherein the first electrode is a hybrid electrode having a high work function and high conductivity, and
wherein a work function-tuning layer is positioned between the photoactive layer and the conductivity-tuning layer in the hybrid electrode having a high work function and high conductivity.
